(19) United States
(12) Patent Application Publication
(10) Pub. No.: US 2026/0206637 A1
(43) Pub. Date: Jul. 16, 2026

(54) SEMICONDUCTOR PACKAGE AND METHOD FOR FABRICATING THE SAME

(71) Applicant: SAMSUNG ELECTRONICS CO., LTD., Suwon-si (KR)

(72) Inventors: Jiyeon PARK, Suwon-si (KR); Kyungseok OH, Suwon-si (KR)

(73) Assignee: SAMSUNG ELECTRONICS CO., LTD., Suwon-si (KR)

(21) Appl. No.: 19/300,366

(22) Filed: Aug. 14, 2025

(30) Foreign Application Priority Data
Jan. 10, 2025 (KR) 10-2025-0004054

(51) Int. Cl. H01L 23/31; H01L 23/00; H01L 23/48; H01L 23/538; H01L 25/04

(52) U.S. Cl. CPC H10W 74/147; H10W 20/20; H10W 90/00; H10W 70/611; H10W 70/685; H10W 72/07355; H10W 72/351; H10W 72/387; H10W 90/792

(57) ABSTRACT

A semiconductor package includes a semiconductor chip including a semiconductor substrate and a chip interconnection structure, an upper bonding layer in contact with the chip interconnection structure, a lower bonding layer having a width greater than a width of the upper bonding layer and is dielectric-dielectric bonded with the upper bonding layer, an upper bonding pad that is wrapped by the upper bonding layer, a lower bonding pad that is wrapped by the lower bonding layer and is metal-metal bonded with the upper bonding pad, and an etching stop layer configured to cover a side surface of the upper bonding layer and an upper surface of the lower bonding layer.

### CROSS-REFERENCE TO RELATED APPLICATIONS

This application claims the benefit of Korean Patent Application No. 10-2025-0004054, filed on Jan. 10, 2025, in the Korean Intellectual Property Office, the disclosure of which is incorporated herein by reference in its entirety.

### BACKGROUND

### 1. Field of the Invention

Example embodiments relate to a semiconductor package and a method of manufacturing the same.

### 2. Description of the Related Art

With the rapid development of the electronics industry and the needs of users, electronic devices are becoming smaller, lighter and more multifunctional, and semiconductor packages used in electrical devices are also required to be smaller, lighter and more multifunctional. For this, by integrating two or more types of semiconductor chips into one semiconductor package, high-capacity and multi-functionality of semiconductor packages have become possible while drastically reducing the size of the semiconductor package.

Meanwhile, in order to achieve high capacity in semiconductor packages, it is necessary to stack semiconductor chips. The method of stacking semiconductor chips can be broadly classified into the chip to chip (C2C) method, the chip to wafer (C2W) method, and the wafer to wafer (W2W) method. The C2C method is a method of stacking chips in units of chips, and the W2W method is a method of stacking wafers and then manufacturing chips through a dicing process. The C2W method has characteristics that are between the C2C method and the W2W method.

### SUMMARY

An aspect provides a semiconductor package with improved process stability.

Another aspect provides a method of manufacturing the semiconductor package with improved process stability.

The technical tasks to be achieved by the present example embodiments are not limited to the technical tasks described above, and other technical tasks may be inferred from the following example embodiments by those skilled in the art.

According to an aspect, there is provided a semiconductor package including a semiconductor chip comprising a semiconductor substrate and a chip interconnection structure, an upper bonding layer in contact with the chip interconnection structure, a lower bonding layer having a width greater than a width of the upper bonding layer, in which the lower bonding layer is dielectric-dielectric bonded with the upper bonding layer, an upper bonding pad that is wrapped by the upper bonding layer, a lower bonding pad that is wrapped by the lower bonding layer and is metal-metal bonded with the upper bonding pad, and an etching stop layer covering a side surface of the upper bonding layer and an upper surface of the lower bonding layer.

According to an aspect, there is provided a semiconductor package including a first semiconductor chip comprising a first semiconductor substrate with an active surface and an inactive surface that are opposite to each other, a plurality of first through electrodes penetrating the first semiconductor substrate, and a first chip interconnection structure on the active surface of the first semiconductor substrate, a plurality of second semiconductor chips each of which includes a second semiconductor substrate with an active surface and an inactive surface that are opposite to each other, a plurality of second through electrodes penetrating the second semiconductor substrate, and a second chip interconnection structure on the active surface of the second semiconductor substrate, a first upper bonding layer in contact with the first chip interconnection structure, a first lower bonding layer having a width greater than a width of the first upper bonding layer, in which the first lower bonding layer is dielectric-dielectric bonded with the first upper bonding layer, a first upper bonding pad that is wrapped by the first upper bonding layer, a first lower bonding pad that is wrapped by the first lower bonding layer, and is metal-metal bonded with the first upper bonding pad, a second upper bonding layer on the inactive surface of the first semiconductor chip, a second lower bonding layer being dielectric-dielectric bonded with the second upper bonding layer, a second upper bonding pad that is wrapped by the second upper bonding layer, a second lower bonding pad that is wrapped by the second lower bonding layer, and is metal-metal bonded with the second upper bonding pad; and a first etching stop layer covering an upper surface of the first lower bonding layer that does not overlap the first upper bonding layer, and a side surface of the first upper bonding layer.

According to an aspect, there is provided a semiconductor package including a redistribution structure, a semiconductor chip comprising a semiconductor substrate with an active surface and an inactive surface that are opposite to each other on the redistribution structure, and a chip interconnection structure on the active surface of the semiconductor substrate, an upper bonding layer that is in contact with the chip interconnection structure and has a first width, a lower bonding layer that is in contact with the upper bonding layer under the upper bonding layer, and has a second width greater than the first width, an upper bonding pad wrapped by the upper bonding layer, a lower bonding pad that is wrapped by the lower bonding layer, and is in contact with the upper bonding pad, an etching stop layer extending along an upper surface of the lower bonding layer that does not overlap the upper bonding layer and a side surface of the upper bonding layer, and includes a material having an etching selectivity with respect to the upper bonding layer and the lower bonding layer, a stopper that extends along an upper surface of the etching stop layer and a side surface of the semiconductor chip, and a gap-fill layer wrapping the stopper, in which the upper surface of the etching stop layer is coplanar with an upper surface of the upper bonding layer.

According to an aspect, there is provided a method of manufacturing a semiconductor package, the method including preparing a wafer including a lower bonding pad and a lower bonding layer wrapping the lower bonding pad on an upper surface, bonding a semiconductor chip including an upper bonding pad and an upper bonding layer wrapping the upper bonding pad onto the wafer by metal-metal bonding between the lower bonding pad and the upper bonding pad and dielectric-dielectric bonding between the lower bonding layer and the upper bonding layer, forming an etching stop layer on an upper surface of the lower bonding layer that does not overlap the upper bonding layer, and removing an upper end portion of the semiconductor chip with an etching process, and the etching stop layer covers the upper surface of the lower bonding layer and an entire side surface of the upper bonding layer.

According to example embodiments, it is possible to provide a semiconductor package that includes an etching stop layer covering a side surface and an upper surface of a dielectric layer in order for the dielectric layer not to be exposed when semiconductor chips are stacked on a wafer using a hybrid bonding method. By the etching stop layer covering the side surface and the upper surface of the dielectric layer, oxidation of the dielectric layer may be prevented in the etching process.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a cross-sectional view illustrating a semiconductor package according to an example embodiment;

FIG. 2 is an enlarged view illustrating a portion marked “CX1” in FIG. 1;

FIG. 3 is an enlarged view corresponding to FIG. 2, illustrating a semiconductor package according to another example embodiment;

FIG. 4 is a cross-sectional view illustrating a semiconductor package according to another example embodiment;

FIG. 5 is an enlarged view illustrating a portion marked “CX2” in FIG. 4;

FIG. 6 is a cross-sectional view illustrating a semiconductor package according to another example embodiment;

FIG. 7 is a cross-sectional view illustrating a semiconductor package according to another example embodiment;

FIGS. 8, 9, 10, 11, 12, 13, 14, 15, 16, 17, and 18 are cross-sectional views sequentially illustrating a process for manufacturing a semiconductor package illustrated in FIG. 1;

FIGS. 19, 20, 21, 22, and 23 are cross-sectional views sequentially illustrating an operation of a process for manufacturing a semiconductor package illustrated in FIG. 6; and

FIGS. 24, 25, 26, 27, and 28 are cross-sectional views sequentially illustrating an operation of a process for manufacturing a semiconductor package illustrated in FIG. 7.

### DETAILED DESCRIPTION

Hereinafter, example embodiments of the present invention will be described in detail with reference to the attached drawings. The same reference numerals are used for identical elements in the drawings, and duplicate descriptions of these are omitted.

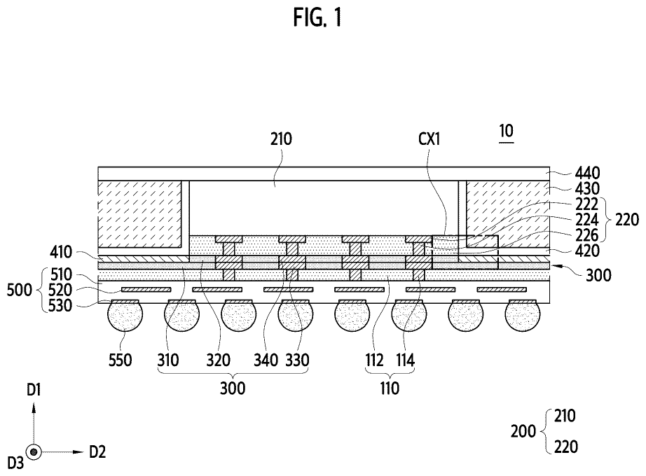

FIG. 1 is a cross-sectional view illustrating a semiconductor package 10 according to an example embodiment.

According to an example embodiment, the semiconductor package 10 may include a connection structure 110, a semiconductor chip 200, a chip bonding structure 300, an etching stop layer 410, a stopper 420, a gap-fill layer 430, a heat dissipation member 440, a redistribution structure 500, and an external connection terminal 550.

According to an example embodiment, the semiconductor chip 200 may include a semiconductor substrate 210 and a chip interconnection structure 220. The semiconductor substrate 210 may have an active surface and an inactive surface that are opposite to each other. In the example embodiment, a surface intersecting the first direction D1 of the semiconductor substrate 210 may be the inactive surface, and a surface intersecting the opposite direction of the first direction (−D1 direction) may be the active surface. In the present disclosure, the first direction D1 may be the direction intersecting the widest surface of the semiconductor substrate 210, and the second direction D2 may be parallel to the first direction D1. The third direction D3 may be a direction parallel to the widest surface of the semiconductor substrate 210, and at the same time, may be a direction intersecting with the second direction D2. For convenience of explanation, in the present disclosure, the relative position along the first direction D1 is expressed as over or under. In the present disclosure, the longitudinal direction means the direction in which an element extends.

According to an example embodiment, the semiconductor substrate 210 constitutes a body of the semiconductor chip 200 and may include silicon (Si). The material of the semiconductor substrate 210 is not limited to silicon. For example, the semiconductor substrate 210 may include other semiconductor materials such as germanium (Ge), Si—Ge, or group III-V compounds such as GaP, GaAs, GaSb and so on. Further, in some example embodiments, the semiconductor substrate 210 may be a silicon-on-insulator (SOI) substrate or a germanium-on-insulator (GOI) substrate. Meanwhile, the semiconductor substrate 210 may include an integrated circuit layer positioned adjacent to the chip interconnection structure 220. A plurality of integrated devices for performing operations of the semiconductor chip 200 may be arranged over the integrated circuit layer.

According to an example embodiment, the plurality of integrated devices may include, for example, metal-oxide-semiconductor field effect transistors (MOSFETs) such as complementary metal-oxide semiconductor (CMOS) transistors, system large scale integration (LSI), flash memory, DRAM, SRAM, EEPROM, PRAM, MRAM, or RERAM, image sensors such as CMOS imaging sensor (CIS), micro-electro-mechanical system (MEMS), active components, passive components and so on.

According to an example embodiment, the chip interconnection structure 220 may include a chip interconnection pattern 222, a chip interconnection via 224, and a chip interconnection insulating layer 226. The chip interconnection structure 220 may be positioned below the semiconductor substrate 210. A plurality of chip interconnection patterns 222 may be provided in the chip interconnection insulating layer 226. Some of the plurality of chip interconnection patterns 222 may be exposed pads on the upper surface of the chip interconnection insulating layer 226. FIG. 1 illustrates only the chip interconnection pattern 222 in the shape of a pad, but in an example embodiment, when the chip interconnection insulating layer 226 is arranged in two or more layers, different chip interconnection patterns 222 having different vertical levels may be interconnected through the chip interconnection via 224. In some example embodiments, the chip interconnection pattern 222 may have a thickness of about 0.5 μm or less.

According to an example embodiment, the lower surface of the chip interconnection via 224 may be exposed on the lower surface of the chip interconnection insulating layer 226. In an example embodiment, the upper surface of the chip interconnection via 224 may be connected to the lower surface of the chip interconnection pattern 222. The chip interconnection via 224 may be configured for vertical wiring within the chip interconnection insulating layer 226. FIG. 1 illustrates only the chip interconnection via 224 having the same vertical level, but in an example embodiment, when the chip interconnection insulating layer 226 is arranged in two or more layers, a plurality of chip interconnection vias 224 may be provided with different vertical levels.

According to an example embodiment, the chip interconnection pattern 222 and the chip interconnection via 224 may include a metal, for example, copper (Cu), aluminum (Al), or tungsten (W), but the chip interconnection pattern 222 and the chip interconnection via 224 are not limited thereto. A barrier film may be interposed between the chip interconnection pattern 222 and the chip interconnection insulating layer 226 or between the chip interconnection via 224 and the chip interconnection insulating layer 226. The thickness of the barrier film may be 50 Å to 1000 Å. The barrier film may include titanium (Ti), tantalum (Ta), titanium nitride (TiN), or tantalum nitride (TaN). The chip interconnection insulating layer 226 may include silicon oxide, silicon nitride, silicon oxynitride, or an insulating material having a lower dielectric constant than silicon oxide, or a combination of these elements. In some example embodiments, the chip interconnection insulating layer 226 may include a tetraethyl orthosilicate (TEOS) film, or may include an ultra-low K (ULK) film having an ultra-low dielectric constant K of about 2.2 to 2.4. The ULK film may include a SiOC film or a SiCOH film.

According to an example embodiment, the connection structure 110 may include an insulating layer 112, and a via 114. The connection structure 110 may be placed between a lower bonding layer 310 and the redistribution structure 500. The via 114 may be an element for vertical wiring within the insulating layer 112. FIG. 1 illustrates only the vias 114 having the same vertical level, but in an example embodiment, the two or more vias 114 may be provided within the insulating layer 112 at different vertical levels. When the two or more vias 114 are provided within the insulating layer 112, a conductive pattern connecting the two or more vias 114 may be provided within the insulating layer 112. In an example embodiment, the insulating layer 112 may include substantially the same material as the chip interconnection insulating layer 226, and the via 114 may include substantially the same material as the chip interconnection via 224.

According to an example embodiment, the chip bonding structure 300 may include the lower bonding layer 310, an upper bonding layer 320, a lower bonding pad 330, and an upper bonding pad 340. The upper bonding layer 320 may be located under the chip interconnection structure 220, and the lower bonding layer 310 may be located over the connection structure 110. The upper bonding pad 340 may be wrapped by the upper bonding layer 320, and the lower bonding pad 330 may be wrapped by the lower bonding layer 310. The lower surface of the upper bonding pad 340 may be exposed from the upper bonding layer 320, and the upper surface of the lower bonding pad 330 may be exposed from the lower bonding layer 310.

According to an example embodiment, the upper bonding pad 340 and the lower bonding pad 330 may be bonded to each other, and the upper bonding layer 320 and the lower bonding layer 310 may be bonded to each other. The upper bonding pad 340 and the lower bonding pad 330 may be electrically connected by bonding to each other. The upper bonding pad 340 and the lower bonding pad 330 may include a metal, for example, copper (Cu), aluminum (Al), or tungsten (W), but the upper bonding pad 340 and the lower bonding pad 330 are not limited thereto. The upper bonding layer 320 and the lower bonding layer 310 may include at least one of SiO, SiN, SiCN, SiCO, or a polymer material. The polymer material may be benzocyclobutene (BCB), polyimide (PI), polybenzoxazole (PBO), silicone, acrylate or epoxy. In some example embodiments, the upper bonding layer 320 and the lower bonding layer 310 may include the same material. The upper bonding layer 320 and the lower bonding layer 310 may have a thickness of, for example, about 100 nm to 1 μm.

As one exemplary measurement method of the aforementioned thicknesses, a “thickness” of an element having two opposing surfaces may mean an average value of shortest distances between the two targeted surfaces measured in a direction perpendicular to the targeted surfaces at multiple locations (e.g., 3, 5, or 10) at equal intervals (or non-equal intervals, alternatively). Other methods appreciated by one of ordinary skill in the art, even if not described in the present disclosure, may also be used.

A hybrid bonding method may be used for bonding between the lower bonding pad 330 and the upper bonding pad 340, and bonding between the lower bonding layer 310 and the upper bonding layer 320. The hybrid bonding method refers to a bonding method that simultaneously bonds metal and dielectric. For example, as illustrated in FIG. 1, the lower bonding pad 330 may be attached to the upper bonding pad 340, and the lower bonding layer 310 may be attached to the upper bonding layer 320. For example, the lower bonding pad 330 and the upper bonding pad 340 may be bonded to each other by a metal-metal bonding method. The lower bonding layer 310 and the upper bonding layer 320 may be bonded to each other by a dielectric-dielectric bonding method.

According to an example embodiment, the redistribution structure 500 may include a redistribution insulating layer 510, a redistribution pattern 520, and a redistribution pad 530.

According to an example embodiment, the redistribution structure 500 may be placed on the lower surface of the connection structure 110. A plurality of redistribution patterns 520 may be provided in the redistribution insulating layer 510. The plurality of redistribution patterns 520 may be arranged at different vertical levels within the redistribution insulating layer 510. Here, even though not illustrated in FIG. 1 in detail, the redistribution via can be placed within the redistribution insulating layer 510 providing vertical wiring between plurality of redistribution patterns 520. The redistribution via may penetrate a part of the redistribution insulating layer 510 and be connected to some of the plurality of redistribution patterns 520, respectively. At least some of the plurality of redistribution patterns 520 may be formed together with some of the redistribution vias to form a whole.

According to an example embodiment, a plurality of redistribution pads 530 may be provided along a lower surface of the redistribution insulating layer 510. The plurality of redistribution pads 530 may be connected to some of the plurality of redistribution vias. At least some of the plurality of redistribution pads 530 may be formed together with some of the redistribution vias to form a whole.

According to an example embodiment, the horizontal width and horizontal area of the redistribution structure 500 may be substantially equal to the horizontal width and horizontal area of the lower bonding layer 310, and may be substantially equal to the horizontal width and horizontal area of the connection structure 110. The side surface of the redistribution structure 500, the side surface of the connection structure 110, the side surface of the chip bonding structure 300, the side surface of the etching stop layer 410, and the side surface of the stopper 420 may be aligned with each other.

According to an example embodiment, the redistribution insulating layer 510 may include, for example, a photo imageable dielectric (PID) or a photosensitive polyimide (PSPI). The redistribution pattern 520 and the redistribution pad 530 may include metals or alloys thereof, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga) and ruthenium (Ru). However, the redistribution pattern 520 and the redistribution pad 530 are not limited thereto. In some example embodiments, the redistribution pattern 520 and the redistribution pad 530 may be formed by depositing a metal or a metal alloy on a seed layer including titanium (Ti), titanium nitride, or titanium tungsten.

According to an example embodiment, the external connection terminals 550 may be attached to the plurality of redistribution pads 530. The external connection terminals 550 may include, for example, solder balls, bumps, UBM (under bump metallurgy) and so on. The external connection terminal 550 may contain metals such as, but not limited to, tin (Sn).

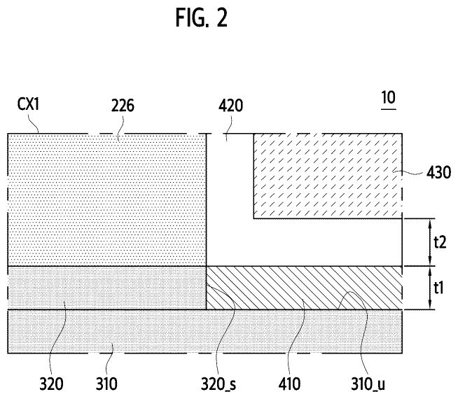

According to an example embodiment, the etching stop layer 410 may cover the upper surface of the lower bonding layer 310 that does not overlap the upper bonding layer 320 and the side surface of the upper bonding layer 320. The structure of the etching stop layer 410 is described in detail later with reference to FIG. 2.

According to an example embodiment, the stopper 420 may cover the upper surface of the etching stop layer 410 and a side surface of the semiconductor chip 200. The stopper 420 may extend conformally along the upper surface of the etching stop layer 410 to a uniform thickness. Further, the stopper 420 may extend conformally along the side surface of the semiconductor chip 200 with a uniform thickness. In other words, the stopper 420 may cover a side surface of the semiconductor substrate 210 and the side surface of the chip interconnection insulating layer 226. The top surface of the stopper 420 may be placed to be coplanar with the upper surface of the semiconductor chip 200. For example, the stopper 420 may include silicon nitride. However, the material included in the stopper 420 is not limited to the silicon nitride.

According to an example embodiment, the gap-fill layer 430 may wrap the stopper 420. The gap-fill layer 430 may cover a portion of the outer side surface and the upper surface of the stopper 420. The gap-fill layer 430 may overlap a portion of the lower bonding layer 310 not overlapping with the upper bonding layer 320 in the first direction D1. The gap-fill layer 430 may not cover the upper surface of the semiconductor chip 200. The gap-fill layer 430 may include an organic material. For example, the gap-fill layer 430 may include polymers such as Tetraethyl orthosilicate (TEOS), Polyimide (PI), PolyBenzoxazole (PBO), PolyHydroxyStyrene (PHS), epoxy, and BenzoCycloButene (BCB) series. However, the material of the gap-fill layer 430 is not limited to the materials above. The gap-fill layer 430 may not contain a photosensitizer, based on its non-photosensitive characteristics. However, according to an example embodiment, the gap-fill layer 430 may also include a photosensitive material containing a photosensitizer.

According to an example embodiment, the heat dissipation member 440 may be placed on the semiconductor chip 200. The heat dissipation member 440 may extend along an upper surface of the semiconductor substrate 210, the top surface of the stopper 420, and the upper surface of the gap-fill layer 430. The side surface of the heat dissipation member 440 may be aligned with the side surface of the gap-fill layer 430. The heat dissipation member 440 may include a material having high thermal conductivity, such as a metal or metal nitride. In some example embodiments, the heat dissipation member 440 may include aluminum, titanium, titanium nitride, nickel, nickel vanadium, silver, gold, copper, or combinations thereof.

FIG. 2 is an enlarged view illustrating a portion marked “CX1” in FIG. 1.

For convenience of explanation below, FIG. 2 is referred to together with FIG. 1 in describing example embodiments. The etching stop layer 410 may cover an upper surface 310_u of the lower bonding layer 310 that does not overlap with the upper bonding layer 320, and cover a side surface 320_s of the upper bonding layer 320. Here, in order for the upper surface 310_u of the lower bonding layer 310 not to be exposed, the etching stop layer 410 may cover the entire upper surface 310_u of the lower bonding layer 310 that does not overlap with the upper bonding layer 320. Further, in order to prevent the side surface 320_s of the upper bonding layer 320 from being exposed, the etching stop layer 410 may cover the entire side surface 320_s of the upper bonding layer 320. As will be described later, in order to prevent the upper bonding layer 320 and the lower bonding layer 310 from being exposed and oxidized in the etching process, the etching stop layer 410 may cover the side surface 320_s of the upper bonding layer 320 and the upper surface 310_u of the lower bonding layer 310. Further, in order to prevent the upper bonding layer 320 and the lower bonding layer 310 from being etched together with the semiconductor substrate 210 in the etching process, the etching stop layer 410 having etching selectivity for the semiconductor substrate 210 may cover the side surface 320_s of the upper bonding layer 320 and the upper surface 310_u of the lower bonding layer 310.

According to an example embodiment, the etching stop layer 410 may extend along the upper surface 310_u of the lower bonding layer 310 with a uniform thickness. For example, the first thickness t1 of the etching stop layer 410 may be in the range from 200 nm to 400 nm. The upper surface of the etching stop layer 410 may be placed to be coplanar with the upper surface of the upper bonding layer 320, and the lower surface of the etching stop layer 410 may be placed to be coplanar with the lower surface of the upper bonding layer 320. Therefore, according to an example embodiment, the thickness of the upper bonding layer 320 and the thickness of the etching stop layer 410 may be substantially the same. However, according to an example embodiment, the thickness of the upper bonding layer 320 and the thickness of the etching stop layer 410 are not necessarily the same. When the upper surface 310_u of the lower bonding layer 310 that does not overlap with the upper bonding layer 320 is not located on the same plane as the upper surface area of the lower bonding layer 310 that overlaps the upper bonding layer 320, the thickness of the upper bonding layer 320 and the thickness of the etching stop layer 410 may be different. According to an example embodiment, the etching stop layer 410 may include a material having etching selectivity with respect to the semiconductor substrate 210, the lower bonding layer 310, and the upper bonding layer 320. The etching stop layer 410 may include, for example, AlO. The AlO is a material that has etching selectivity for silicon (Si).

According to an example embodiment, when the first thickness t1 of the etching stop layer 410 located on the lower bonding layer 310 is provided to be less than 200 nm, in the process of etching the semiconductor substrate 210, the etching stop layer 410 may also be etched, exposing the upper bonding layer 320 or the lower bonding layer 310. Further, when the thickness of the lower bonding layer 310 is provided to be greater than 400 nm, the material for forming the lower bonding layer 310 may be used excessively beyond necessity.

According to an example embodiment, the stopper 420 may extend along the upper surface of the etching stop layer 410 and the side surface of the chip interconnection insulating layer 226 with a uniform thickness. For example, the second thickness t2 of the stopper 420 may be in the range from 300 nm to 500 nm. As will be described later, the upper end portion of the gap-fill layer 430 may be polished through a chemical mechanical polishing (CMP) process. In the process of polishing the gap-fill layer 430 using the CMP process, the stopper 420 may prevent the semiconductor substrate 210 from being polished by utilizing the difference in polishing ratio or may serve to indicate the position of the semiconductor substrate 210.

According to an example embodiment, when the second thickness t2 of the stopper 420 is provided to be less than 300 nm, in the CMP process for the gap-fill layer 430, the stopper 420 may also be polished, exposing the semiconductor substrate 210. Further, when the thickness of the stopper 420 is provided to be greater than 500 nm, the material used to form the stopper 420 may be excessively used.

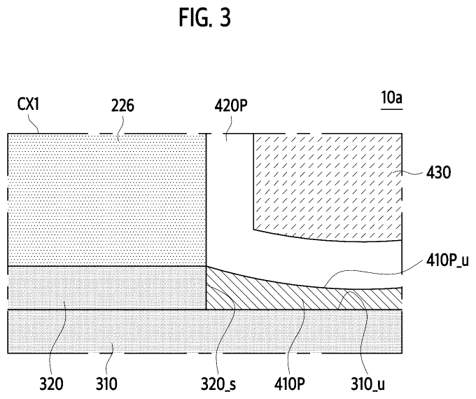

FIG. 3 is an enlarged view corresponding to FIG. 2, illustrating a semiconductor package 10a according to another example embodiment.

The semiconductor package 10a illustrated in FIG. 3 is almost identical or similar to the semiconductor package 10 illustrated in FIG. 2 except that an etching stop layer 410P has a curved upper surface 410P_u and the thickness of the stopper 420P varies along the length direction. Therefore, descriptions of elements already mentioned with reference to FIG. 1 and FIG. 2 are omitted below, or briefed.

Referring to FIG. 3, the etching stop layer 410P may have a thickness that varies along the length direction on the lower bonding layer 310. FIG. 3 illustrates that the vertical level of the upper surface 410P_u of the etching stop layer 410P gradually decreases along the lateral direction (the first direction (the X direction) and/or the second direction (the Y direction)). However, according to an example embodiment, the thickness of the etching stop layer 410P may be repeatedly increased and decreased along the longitudinal direction. According thereto, the upper surface 410P_u of the etching stop layer 410P may also have a vertical level that increases and decreases repeatedly along the length direction. When the etching stop layer 410P has the curved upper surface 410P_u, the etching stop layer 410P may cover the entire side surface 320_s of the upper bonding layer 320 in order for the side surface 320_s of the upper bonding layer 320 not to be exposed.

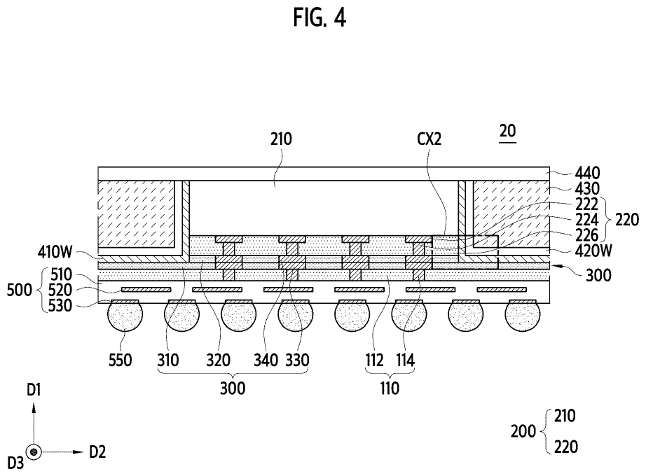

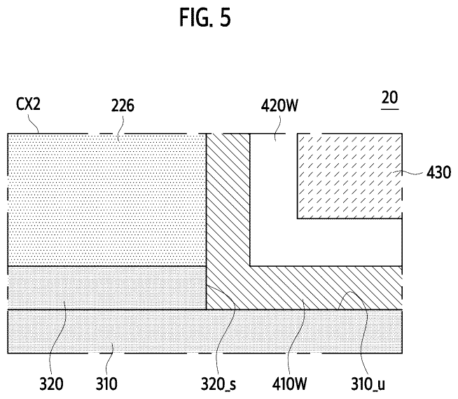

FIG. 4 is a cross-sectional view illustrating a semiconductor package 20 according to another example embodiment. FIG. 5 is an enlarged view illustrating a portion marked “CX2” in FIG. 4.

The semiconductor package 20 illustrated in FIG. 4 and FIG. 5 is almost identical or similar to the semiconductor package 10 illustrated in FIG. 1 except that an etching stop layer 410W covers the side surface of the semiconductor chip 200. Therefore, descriptions of elements already mentioned with reference to FIG. 1 and FIG. 2 are omitted below, or briefed.

Referring to FIG. 4 and FIG. 5, the etching stop layer 410W may extend along the upper surface 310_u of the lower bonding layer 310, and at the same time, may extend along the side surface of the semiconductor chip 200. The etching stop layer 410W may cover the side surface 320_s of the upper bonding layer 320, the side surface of the chip interconnection insulating layer 226, and the side surface of the semiconductor substrate 210. Here, the top surface of the etching stop layer 410W may be placed to be coplanar with the upper surface of the semiconductor substrate 210. Further, the top surface of the etching stop layer 410W may be placed to be coplanar with the upper surface of the gap-fill layer 430.

According to an example embodiment, by the etching stop layer 410W covering the side surface of the chip interconnection insulating layer 226 and the side surface of the semiconductor substrate 210, in the process of etching the upper end portion of the semiconductor substrate 210, the side of the chip interconnection insulating layer 226 or the side of the semiconductor substrate 210 may not be exposed. Therefore, in the process of etching the upper end portion of the semiconductor substrate 210, the side of the semiconductor substrate 210 may not be etched.

According to an example embodiment, the stopper 420W may extend longitudinally along the upper surface and the side surface of the etching stop layer 410W. The stopper 420W may extend along the side surface of the etching stop layer 410W in order for the side surface of the etching stop layer 410W not to be exposed. The top surface of the stopper 420W may be placed to be coplanar with the top surface of the etching stop layer 410W, the upper surface of the semiconductor substrate 210, and the top surface of the etching stop layer 410W.

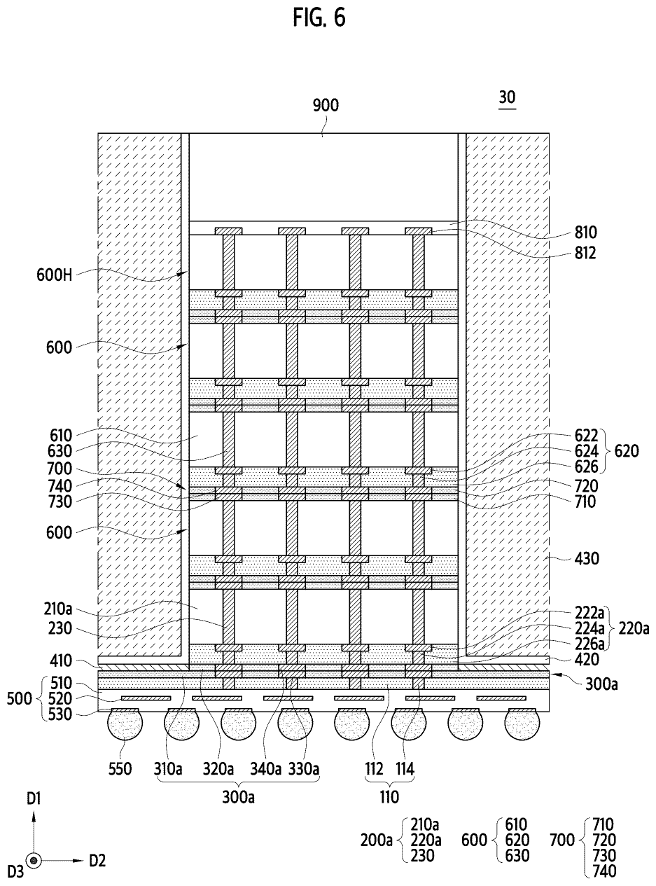

FIG. 6 is a cross-sectional view illustrating a semiconductor package 30 according to another example embodiment.

The semiconductor package 30 illustrated in FIG. 6 is almost identical or similar to the semiconductor package illustrated in FIG. 1 except that a plurality of semiconductor chips are provided, that are stacked along the first direction D1. Therefore, descriptions of elements already mentioned with reference to FIG. 1 are omitted below, or briefed.

Referring to FIG. 6, the semiconductor package 30 may include a first semiconductor chip 200a, a plurality of second semiconductor chips 600, a first chip bonding structure 300a, a plurality of second chip bonding structures 700, a supportive binding insulation layer 810, an upper surface chip connecting pad 812, and a supporting dummy substrate 900.

FIG. 6 illustrates that the semiconductor package 30 contains four second semiconductor chips 600, but the present disclosure is not limited thereto. For example, the semiconductor package 30 may contain two or more second semiconductor chips 600. In some example embodiments, the semiconductor package 30 may contain a plurality of second semiconductor chips 600 of which number is a multiple of 4. The plurality of second semiconductor chips 600 may be sequentially stacked on the first semiconductor chip 200a.

According to an example embodiment, the first semiconductor chip 200a and the plurality of second semiconductor chips 600 included in the semiconductor package 30 may be electrically connected via the second chip bonding structure 700 to transmit and receive signals, and provide power and ground. For example, among the plurality of second semiconductor chips 600, the bottom semiconductor chip and the first semiconductor chip 200a may be electrically connected through a first lower bonding pad 330a and a first upper bonding pad 340a. Further, the plurality of second semiconductor chips 600 may be electrically connected through a second lower bonding pad 730 and a second upper bonding pad 740. The first chip bonding structure 300a illustrated in FIG. 6 may be substantially identical to the chip bonding structure 300 illustrated in FIG. 1.

In the semiconductor package 30, the first semiconductor chip 200a may be placed in order for an active surface of a first semiconductor substrate 210a to face downward and an inactive surface to face upward. Therefore, unless otherwise specified in the present disclosure, the upper surface of the first semiconductor chip 200a of the semiconductor package 30 refers to the side facing the inactive surface of the first semiconductor substrate 210a, and the lower surface of the first semiconductor chip 200a refers to the side facing the active surface. However, when explaining based on the first semiconductor chip 200a, the lower surface of the first semiconductor chip 200a toward which the active surface of the first semiconductor substrate 210a faces may be referred to as the front surface of the first semiconductor chip 200a, and the upper surface of the first semiconductor chip 200a toward which the inactive surface faces may be called the back surface of the first semiconductor chip 200a.

The first semiconductor chip 200a may include the first semiconductor substrate 210a, a first chip interconnection structure 220a, and a first through electrode 230. The first chip interconnection structure 220a may include a first chip interconnection pattern 222a, a first chip interconnection via 224a, and a first chip interconnection insulating layer 226 a. The first chip interconnection structure 220a illustrated in FIG. 6 has substantially the same configuration as the chip interconnection structure 220 illustrated in FIG. 1, and thus detailed explanations are omitted.

According to an example embodiment, each of the plurality of second semiconductor chips 600 may include a second semiconductor substrate 610 having an active surface and an inactive surface that are opposite to each other, a second chip interconnection structure 620 on the active surface of the second semiconductor substrate 610, and a second through electrode 630.

In some example embodiments, among the plurality of second semiconductor chips 600, a plurality of upper surface chip connecting pads 812 may be arranged on the upper surface of the semiconductor chip located at the top. The plurality of upper surface chip connecting pads 812 may be arranged on the upper surface of the second semiconductor chip 600 to be connected to a plurality of second through electrodes 630.

According to an example embodiment, the length, or the thickness, in each of the plurality of second semiconductor chips 600 in the first direction D1 may have approximately the same value. Further, the length in the first direction D1 of the first semiconductor chip 200a may have approximately the same value as the length in each of the plurality of second semiconductor chips 600 in the first direction D1. For example, the length of the first semiconductor chip 200a in the first direction D1 and the length of each of the plurality of second semiconductor chips 600 in the first direction D1 may be about 50 μm to about 90 μm.

As used herein, the expression “approximately the same value” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

According to an example embodiment, in the semiconductor package 30, each of the plurality of second semiconductor chips 600 may be sequentially stacked on the first semiconductor chip 200a along the first direction D1, while the active surface facing downward, or, toward the first semiconductor chip 200a. Therefore, unless otherwise specified in the present disclosure, the upper surface of the second semiconductor chip 600 included in the semiconductor package 30 may refer to the side facing the inactive surface of the second semiconductor substrate 610, and the lower surface of the second semiconductor chip 600 may refer to the side facing the active surface of the second semiconductor substrate 610. However, when explaining based on the second semiconductor chip 600, the lower surface of the second semiconductor chip 600 toward which the active surface of the semiconductor substrate 610 faces may be called the front surface of the second semiconductor chip 600, and the upper surface of the second semiconductor chip 600 facing the inactive surface may be called the back surface of the second semiconductor chip 600.

According to an example embodiment, the material included in the second semiconductor substrate 610 may be substantially identical to the material included in the semiconductor substrate 210 mentioned with reference to FIG. 1. Therefore, detailed explanations are omitted.

Meanwhile, the second semiconductor substrate 610 may include an integrated circuit layer positioned adjacent to the second chip interconnection structure 620. A plurality of integrated devices for performing operations of the second semiconductor chip 600 may be placed in the integrated circuit layer. The plurality of integrated devices of the second semiconductor chip 600 may include, for example, MOSFETs such as CMOS transistors, system LSIs, flash memories, DRAMs, SRAMs, EEPROMs, PRAMs, MRAMs, and RERAMs, image sensors such as CIS, MEMS, active components, and passive components.

According to an example embodiment, at least one of the first semiconductor chip 200a and the plurality of second semiconductor chips 600 may be a memory semiconductor chip. In some example embodiments, the first semiconductor chip 200a includes a serial-parallel conversion circuit and may be a buffer chip for controlling the plurality of second semiconductor chips 600, and the plurality of second semiconductor chips 600 may be a memory chip including memory cells. For example, the semiconductor package 30 including the first semiconductor chip 200a and the plurality of second semiconductor chips 600 may be a high bandwidth memory (HBM), the first semiconductor chip 200a may be called the HBM controller die, and each of the plurality of second semiconductor chips 600 may be referred to as a DRAM die.

According to an example embodiment, the second chip interconnection structure 620 may include a second chip interconnection pattern 622, a second chip interconnection via 624, and a second chip interconnection insulating layer 626. In some example embodiments, the second chip interconnection pattern 622 may have a thickness of about 0.5 μm or less.

According to an example embodiment, the plurality of second chip interconnection pattern 622 may be provided within the second chip interconnection insulating layer 626. Some of the plurality of second chip interconnection patterns 622 may be exposed pads on the upper surface of the second chip interconnection insulating layer 626. Even though FIG. 6 illustrates only the second chip interconnection pattern 622 in the pad shape, according to an example embodiment, when the second chip interconnection insulating layer 626 is arranged in two or more layers, different second chip interconnection patterns 622 having different vertical levels may be interconnected through the second chip interconnection via 624.

According to an example embodiment, the lower surface of the second chip interconnection via 624 may be exposed on the lower surface of the second chip interconnection insulating layer 626. In an example embodiment, the upper surface of the second chip interconnection via 624 may be connected to the lower surface of the second chip interconnection pattern 622. The second chip interconnection via 624 may be configured for vertical wiring within the second chip interconnection insulating layer 626. FIG. 6 illustrates only the second chip interconnection via 624 having one vertical level, but according to an example embodiment, when the second chip interconnection pattern 622 is arranged in two or more layers, the plurality of second chip interconnection vias 624 may be provided with different vertical levels.

According to an example embodiment, the material included in the second chip interconnection via 624 and the second chip interconnection pattern 622 may be substantially identical to the material included in the chip interconnection via 224 and the chip interconnection pattern 222 referred to with reference to FIG. 1. Further, the material included in the second chip interconnection insulating layer 626 may be substantially identical to the material included in the chip interconnection insulating layer 226 referred to with reference to FIG. 1. Therefore, detailed explanation thereon is omitted below.

According to an example embodiment, each of the first through electrode 230 and the second through electrode 630 may be formed with a through silicon via TSV. Each of the first through electrode 230 and the second through electrode 630 may include a conductive plug penetrating each of the first semiconductor substrate 210a and the second semiconductor substrate 610, and a conductive barrier film wrapping the conductive plug. The conductive plug may have a cylindrical shape, and the conductive barrier film may have a cylindrical shape wrapping a side wall of the conductive plug. Between the first through electrode 230 and the first semiconductor substrate 210a, and between the second through electrode 630 and the second semiconductor substrate 610, a via insulating film is interposed to wrap the side walls of the first through electrode 230 and the second through electrode 630. It is apparent that the first through electrode 230 and the second through electrode 630 may be formed in any one of a via-first structure, a via-middle structure and a via-last structure.

FIG. 6 illustrates that a uppermost second semiconductor chip 600H includes the second through electrode 630, but example embodiments are not limited thereto. According to an example embodiment, the uppermost second semiconductor chip 600H may not include the second through electrode 630.

According to an example embodiment, the first chip bonding structure 300a may include a first lower bonding layer 310a, a first upper bonding layer 320a, the first lower bonding pad 330a, and the first upper bonding pad 340a.

The chip bonding structure 300 described with reference to FIG. 1 and the first chip bonding structure 300a illustrated in FIG. 6 may have substantially the same configuration. Therefore, any description that repeating the description provided with reference to FIG. 1 are omitted.

According to an example embodiment, the plurality of second chip bonding structures 700 may be interposed between each of the plurality of second semiconductor chips 600 stacked in the first direction D1. The second chip bonding structure 700 may include a second lower bonding layer 710, a second upper bonding layer 720, the second lower bonding pad 730, and the second upper bonding pad 740. The second upper bonding pad 740 and the second lower bonding pad 730 may be bonded to each other, and the second upper bonding layer 720 and the second lower bonding layer 710 may be bonded to each other. The second upper bonding pad 740 and the second lower bonding pad 730 may be electrically connected by bonding to each other.

According to an example embodiment, the bonding between the second lower bonding pad 730 and the second upper bonding pad 740, and the bonding between the second lower bonding layer 710 and the second upper bonding layer 720 may be a hybrid bonding method. For example, the second lower bonding pad 730 and the second upper bonding pad 740 may be bonded to each other by a metal-metal bonding method. The second lower bonding layer 710 and the second upper bonding layer 720 may be bonded to each other by a dielectric-dielectric bonding method.

According to an example embodiment, the second chip bonding structure 700 may cover the entire upper surface or the entire lower surface of each of a pair of second semiconductor chips 600 facing each other along the first direction D1. The second lower bonding layer 710 and the second lower bonding pad 730 may cover the upper surface of the second semiconductor chip 600 located at the bottom in the pair of the second semiconductor chips 600. Further, the second upper bonding layer 720 and the second upper bonding pad 740 may cover the lower surface of the second semiconductor chip 600 located at the top in the pair of second semiconductor chips 600. The second lower bonding layer 710 and the second upper bonding layer 720 may have flat upper and lower surfaces having substantially the same thickness.

According to an example embodiment, the second lower bonding layer 710 and the second upper bonding layer 720 may include the same material as the lower bonding layer 310 and the upper bonding layer 320 described with reference to FIG. 1. Therefore, any description that is repeating the description provided with reference to FIG. 1 is omitted.

In order to help understand the present disclosure, the second semiconductor chip 600 located at the top among the plurality of second semiconductor chips 600 will be referred to as the uppermost second semiconductor chip 600H. The supporting dummy substrate 900 may be stacked on the uppermost second semiconductor chip 600H. For example, the supporting dummy substrate 900 may contain a semiconductor material such as silicon. In some example embodiments, the supporting dummy substrate 900 may be made only of a semiconductor material. For example, the supporting dummy substrate 900 may be a part of a bare wafer. The length of the supporting dummy substrate 900 in the first direction D1 may have a value greater than the length in the first direction D1 of the first semiconductor chip 200a or have a value greater than the length in the first direction D1 of the second semiconductor chip 600. For example, the length in the first direction D1 of the supporting dummy substrate 900 may be from about 100 μm to about 500 μm.

According to an example embodiment, among the plurality of second semiconductor chips 600, the supportive binding insulation layer 810 may be interposed between the uppermost second semiconductor chip 600H and the supporting dummy substrate 900. The supportive binding insulation layer 810 may be formed by forming an insulating material layer on each of the upper surface of the uppermost second semiconductor chip 600H and the lower surface of the supporting dummy substrate 900, facing each other, and by the insulating materials facing each other becoming one through the diffusion of atoms by heat.

According to an example embodiment, the supportive binding insulation layer 810 may cover the entire lower surface of the supporting dummy substrate 900. In some example embodiments, when the plurality of upper surface chip connecting pads 812 are placed on the upper surface of the uppermost second semiconductor chip 600H, the supportive binding insulation layer 810 may wrap the plurality of upper surface chip connecting pads 812. For example, the supportive binding insulation layer 810 may cover the upper surface, or the inactive surface, of the second semiconductor substrate 610 of the uppermost second semiconductor chip 600H, the side surface and the upper surface of the plurality of upper surface chip connecting pads 812. The plurality of upper surface chip connecting pads 812 may be spaced apart from the supporting dummy substrate 900 with a portion of the supportive binding insulation layer 810 therebetween. In another example embodiment, when the plurality of upper surface chip connecting pads 812 are not placed on the upper surface of the uppermost second semiconductor chip 600H, the supportive binding insulation layer 810 may cover the plurality of second through electrodes 630 exposed on the upper surface of the second semiconductor substrate 610 of the uppermost second semiconductor chip 600H, and exposed on the upper surface of the second semiconductor substrate 610 of the uppermost second semiconductor chip 600H.

According to an example embodiment, the side surfaces of the supporting dummy substrate 900 and the supportive binding insulation layer 810 may be aligned with each other in the first direction D1 with a side surface of each of the plurality of second semiconductor chips 600 and a side surface of the first semiconductor chip 200a, and may be positioned on the same plane. The supportive binding insulation layer 810 may have the same material as the lower bonding layer 310 and the upper bonding layer 320 described with reference to FIG. 1. Therefore, any description that is repeating the description provided with reference to FIG. 1 is omitted.

According to an example embodiment, the redistribution structure 500 may be placed on the lower surface of the connection structure 110. The external connection terminal 550 may be attached to the redistribution pad 530 of the redistribution structure 500. The redistribution structure 500 and the external connection terminal 550 illustrated in FIG. 6 are substantially identical to the redistribution structure 500 and the external connection terminal 550 illustrated in FIG. 1, and thus detailed explanation thereon is omitted below.

According to an example embodiment, the stopper 420 may cover the upper surface of the etching stop layer 410 and the side surfaces of the plurality of second semiconductor chips 600, the side surface of the supportive binding insulation layer 810, and the side surface of the supporting dummy substrate 900. The stopper 420 may extend conformally along the upper surface of the etching stop layer 410 to a uniform thickness. Further, the stopper 420 may cover the side surfaces of the plurality of second semiconductor chips 600 and the side surface of the supportive binding insulation layer 810, and the side surface of the supporting dummy substrate 900. The top surface of the stopper 420 may be placed to be coplanar with the upper surface of the supporting dummy substrate 900. The stopper 420 may have the same material as the stopper 420 described with reference to FIG. 1. Therefore, any description that is repeating the description provided with reference to FIG. 1 is omitted.

According to an example embodiment, the gap-fill layer 430 may wrap the stopper 420. The gap-fill layer 430 illustrated in FIG. 6 is substantially identical to the gap-fill layer 430 illustrated in FIG. 1, and thus any description that is repeating the description provided with reference to FIG. 1 is omitted below.

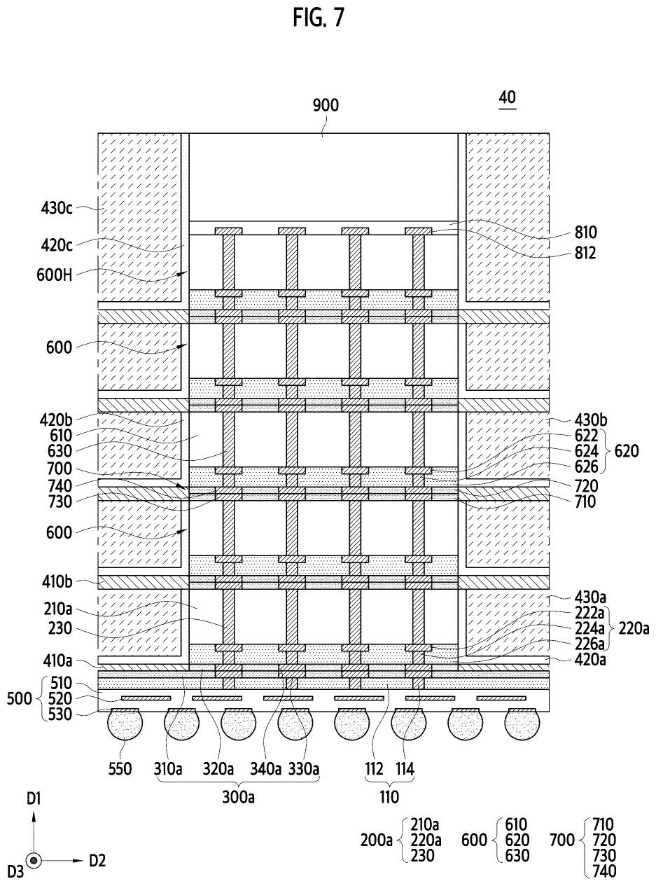

FIG. 7 is a cross-sectional view illustrating a semiconductor package 40 according to another example embodiment.

The semiconductor package 40 illustrated in FIG. 7 is almost identical or similar to the semiconductor package 30 illustrated in FIG. 6 except that the plurality of etching stop layers (a first etching stop layer 410a to a second etching stop layer 410b), the plurality of stoppers (a first stopper 420a to a third stopper 420c) and the plurality of gap-fill layers (a first gap-fill layer 430a to a third gap-fill layer 430c) are provided. Therefore, descriptions of the elements already mentioned with reference to FIG. 1 and FIG. 6 are omitted below, or briefed.

According to an example embodiment, the semiconductor package 40 may include the first etching stop layer 410a and the second etching stop layer 410b, the first stopper 420a to the third stopper 420c, and the first gap-fill layer 430a to the third gap-fill layer 430c. The first etching stop layer 410a is substantially identical to the etching stop layer 410 mentioned with reference to FIG. 1 and FIG. 6, and thus detailed explanations are omitted.

According to an example embodiment, a plurality of second etching stop layers 410b may be provided, and the plurality of second etching stop layers 410b may be spaced apart along the first direction D1. Each of the plurality of second etching stop layers 410b may cover the side surface of the second chip bonding structure 700. Each of the plurality of second etching stop layers 410b may cover the entire side surface of the second lower bonding layer 710 and the entire side surface of the second upper bonding layer 720, in order to prevent the side surface of the second lower bonding layer 710 and the side surface of the second upper bonding layer 720 from being exposed. As will be described later, in order to prevent the second lower bonding layer 710 and the second upper bonding layer 720 from being exposed and oxidized in the etching process, each of the plurality of second etching stop layers 410b may cover the side surface of the second lower bonding layer 710 and the side surface of the second upper bonding layer 720. Further, in order to prevent the second upper bonding layer 720 and the second lower bonding layer 710 from being etched together with the second semiconductor substrate 610 in the etching process, the second etching stop layer 410b having etching selectivity for the second semiconductor substrate 610 may cover the side surface of the second upper bonding layer 720 and an upper surface of the second lower bonding layer 710.

According to an example embodiment, each of the plurality of second etching stop layers 410b may conformally extend along an upper surface of the first gap-fill layer 430a or the upper surface of a plurality of second gap-fill layers 430b. The thickness of the second etching stop layer 410b may be thicker than the thickness of the first etching stop layer 410a. The length, or the thickness, of the second etching stop layer 410b in the first direction D1 may correspond to the sum of the thickness of the second lower bonding layer 710 and the thickness of the second upper bonding layer 720.

According to an example embodiment, the material included in the second etching stop layer 410b is substantially identical to the material included in the etching stop layer 410 illustrated in FIG. 1, and thus detailed explanation thereof is omitted.

According to an example embodiment, the first stopper 420a may cover the upper surface of the first etching stop layer 410a and the side surface of the first semiconductor chip 200a. Further, the upper surface of the first stopper 420a may contact the lower surface of the bottom one of the plurality of second etching stop layers 410b. The first stopper 420a may extend conformally with a uniform thickness along the upper surface of the first etching stop layer 410a and the side surface of the first semiconductor chip 200a. A plurality of second stoppers 420b may be provided. The plurality of second stoppers 420b may cover each of the upper surface of the second etching stop layer 410b and the side surface of the second semiconductor chip 600. Each of the plurality of second stoppers 420b may conformally extend with a uniform thickness along the upper surface of the second etching stop layer 410b and the side surface of the second semiconductor chip 600. The third stopper 420c may cover an upper surface of a top second etching stop layer 410b, a side surface of a uppermost second semiconductor chip 200H, and the side surface of the supporting dummy substrate 900. The third stopper 420c may be extended conformally along the upper surface of the top second etching stop layer 410b, the side surface of the uppermost second semiconductor chip 200H, and the side surface of the supporting dummy substrate 900 with a uniform thickness. The material included in the first stopper 420a to the third stopper 420c is substantially the same as the material included in the stopper 420 illustrated in FIG. 1, and thus detailed explanation thereof is omitted.

According to an example embodiment, the first gap-fill layer 430a may wrap the first stopper 420a. The first gap-fill layer 430a may cover the side surface of the first stopper 420a. The upper surface of the first gap-fill layer 430a may be placed to be coplanar with the top surface of the first stopper 420a and the upper surface of the first semiconductor chip 200a. The first gap-fill layer 430a may not cover the upper surface of the first semiconductor chip 200a. The plurality of second gap-fill layers 430b may be provided. Each of the plurality of second gap-fill layers 430b may wrap the second stopper 420b. The second gap-fill layer 430b may cover the side surface of the second stopper 420b. The upper surface of the second gap-fill layer 430b may be placed to be coplanar with the top surface of the second stopper 420b and the upper surface of the second semiconductor chip 600. Each of the plurality of second gap-fill layers 430b may not cover the upper surface of the second semiconductor chip 600. The third gap-fill layer 430c may wrap the third stopper 420c. The third gap-fill layer 430c may cover the outer side surface of the third stopper 420c. The upper surface of the third gap-fill layer 430c may be placed to be coplanar with the top surface of the third stopper 420c and the upper surface of the supporting dummy substrate 900. The third gap-fill layer 430c may not cover the upper surface of the supporting dummy substrate 900. According to an example embodiment, the first gap-fill layer 430a, the plurality of second gap-fill layers 430b, and the third gap-fill layer 430c may overlap a portion of the first lower bonding layer 310a that does not overlap the upper bonding layer 320a, in the first direction D1.

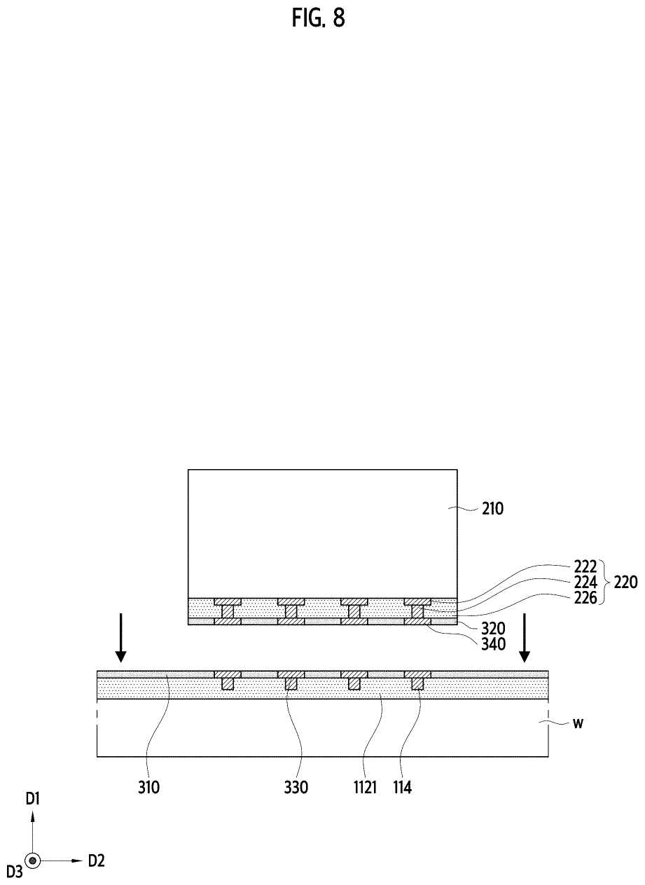

FIG. 8 to FIG. 18 are cross-sectional views sequentially illustrating a process for manufacturing the semiconductor package 10 illustrated in FIG. 1.

Referring to FIG. 8, a method for manufacturing the semiconductor package 10 according to the example embodiment may include, first, preparing a wafer W having an insulating material 1121 and the lower bonding layer 310 on the upper surface. In the insulating material 1121, the via 114 may be provided that penetrates at least a portion of the insulating material 1121 in the first direction D1. The lower surface of the via 114 may not reach the lower surface of the insulating material 1121. In other words, the lower surface of the insulating material 1121 may be located closer to the wafer W than the lower surface of the via 114, and a lower surface of the insulating material 1121 may not be placed to be coplanar with the lower surface of the via 114.

According to an example embodiment, the lower bonding layer 310 may extend along the upper surface of the insulating material 1121. The lower bonding layer 310 may conformally extend with a uniform thickness on the insulating material 1121. According to an example embodiment, the lower bonding pad 330 may be surrounded by the lower bonding layer 310. The upper surface of the lower bonding pad 330 may be placed to be coplanar with the upper surface of the lower bonding layer 310, and the lower surface of the lower bonding pad 330 may be placed to be coplanar with the lower surface of the lower bonding layer 310. Here, the upper end portion of the via 114 may be connected to the lower bonding pad 330.

According to an example embodiment, the semiconductor substrate 210 having the chip interconnection structure 220 and the upper bonding layer 320 formed on the lower surface may be provided spaced apart from the lower bonding layer 310 on the wafer W. The chip interconnection structure 220 may be formed along the lower surface of the semiconductor substrate 210. The chip interconnection pattern 222 of the chip interconnection structure 220 may be connected to the semiconductor substrate 210. The lower end portion of the chip interconnection pattern 222 may be connected to the chip interconnection via 224.

According to an example embodiment, the upper bonding layer 320 may be formed along the lower surface of the chip interconnection structure 220. The upper bonding layer 320 may extend along the lower surface of the chip interconnection structure 220 beneath the chip interconnection structure 220. The upper bonding layer 320 may extend conformally with a uniform thickness under the chip interconnection structure 220. According to an example embodiment, the upper bonding pad 340 may be surrounded by the upper bonding layer 320. The upper surface of the upper bonding pad 340 may be placed to be coplanar with the upper surface of the upper bonding layer 320, and the lower surface of the upper bonding pad 340 may be placed to be coplanar with the lower surface of the upper bonding layer 320.

After then, the semiconductor substrate 210 having the chip interconnection structure 220 and the upper bonding layer 320 provided on a lower end portion may be attached to the lower bonding layer 310. Here, the semiconductor substrate 210 may be aligned so that the lower bonding pad 330 and the upper bonding pad 340 are aligned and in contact with each other.

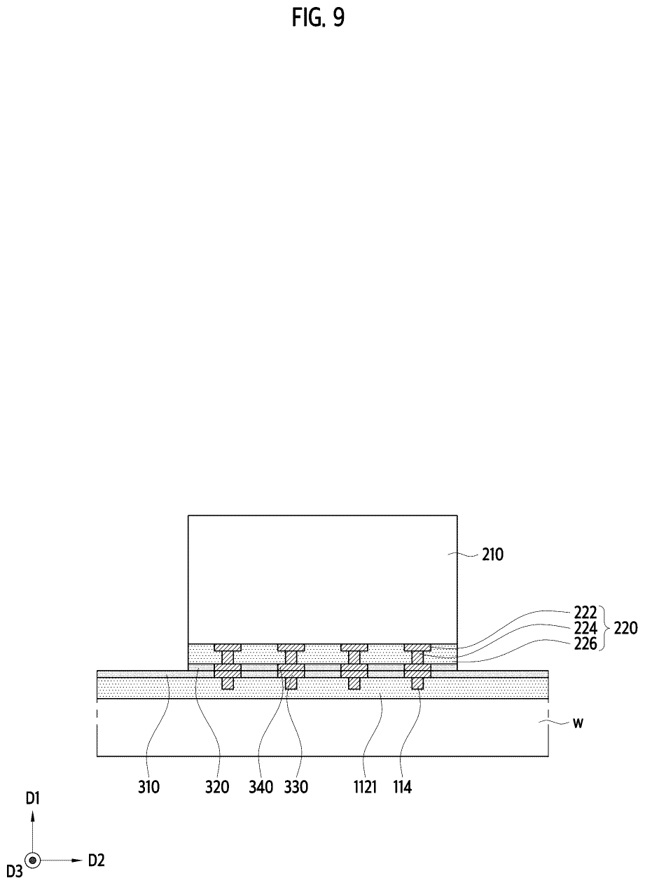

Referring to FIG. 8 and FIG. 9, in the process of positioning the semiconductor substrate 210 on the wafer W, heat and/or pressure are applied, the lower bonding pad 330 and the upper bonding pad 340 are bonded, and the lower bonding layer 310 and the upper bonding layer 320 may be bonded. In some example embodiments, the lower bonding layer 310 and the upper bonding layer 320 may be bonded by covalent bonding. For example, in the process of positioning the upper bonding layer 320 and the upper bonding pad 340 on the wafer W, heat of the first temperature may be applied.

After then, applying heat at a second temperature higher than the first temperature, the upper bonding layer 320 and the lower bonding layer 310 may be bonded to each other to form a single body. In the present disclosure, for convenience of illustration, an interface is illustrated formed between the upper bonding layer 320 and the lower bonding layer 310, but by the above-mentioned shared bond, the upper bonding layer 320 and the lower bonding layer 310 may form a single body, without an interface. The bonding between the upper bonding layer 320 and the lower bonding layer 310 may be dielectric-dielectric bonding.

According to an example embodiment, the upper bonding pad 340 and the lower bonding pad 330, which correspond to each other, may expand due to heat and come into contact with each other, and then may be diffusion-bonded to form a single unit through diffusion of the metal atoms they contain. In the present disclosure, for convenience of illustration, an interface is illustrated formed between the upper bonding pad 340 and the lower bonding pad 330, but the upper bonding pad 340 and the lower bonding pad 330 may form a single body by the diffusion bonding, without an interface. The bonding between the upper bonding pad 340 and the lower bonding pad 330 may be metal-metal bonding.

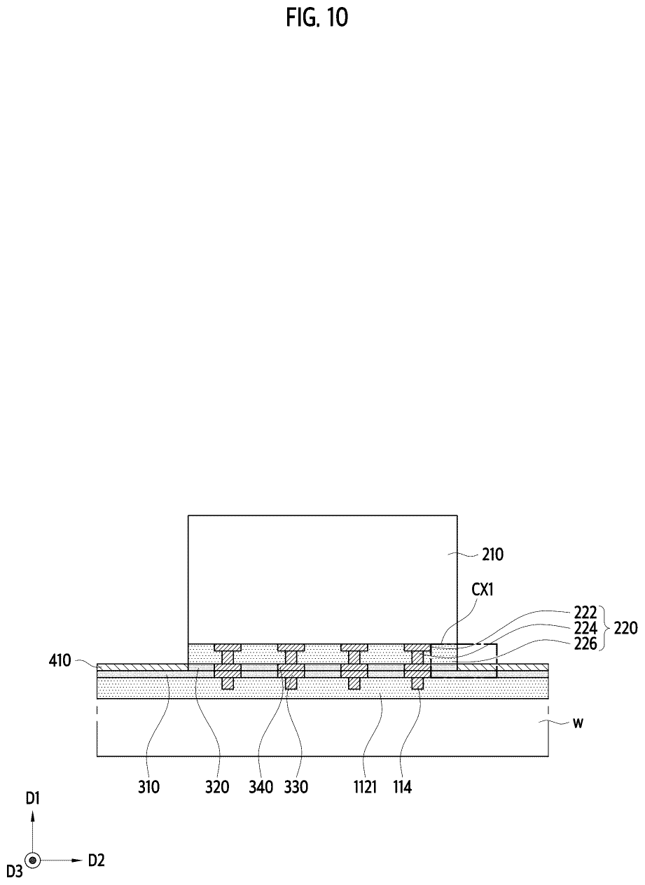

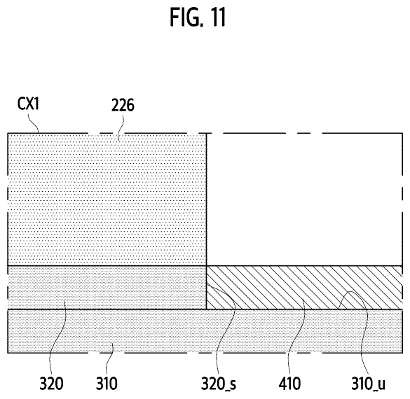

Referring to FIG. 10 and FIG. 11, the etching stop layer 410 may be formed on the upper surface 310_u of the lower bonding layer 310 not overlapping with the upper bonding layer 320. The etching stop layer 410 may be formed to have a conformal thickness by an atomic layer deposition ALD process. The etching stop layer 410 may contact the upper surface 310_u of the lower bonding layer 310, and at the same time, the etching stop layer 410 may be formed to completely cover the side surface 320_s of the upper bonding layer 320. By forming a precursor on the upper surface of the lower bonding layer 310, the etching stop layer 410 may be selectively formed on a side of the upper bonding layer 320 on the upper surface of the lower bonding layer 310. According to an example embodiment, the etching stop layer 410 may completely cover only the side surface of the upper bonding layer 320, and may not cover the side surface of the chip interconnection insulating layer 226.

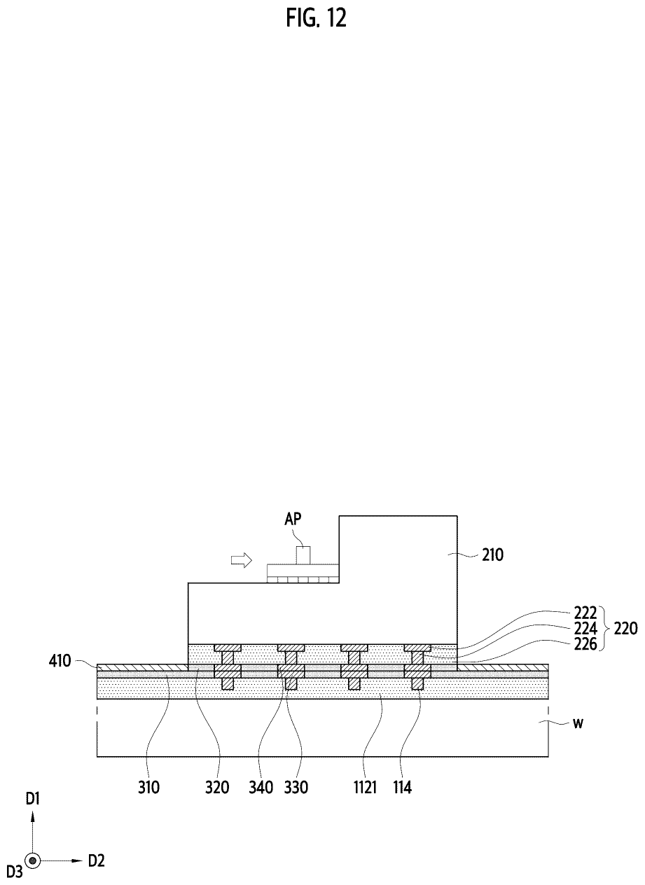

Referring to FIG. 12, after forming the etching stop layer 410 on the lower bonding layer 310, the upper end portion of the semiconductor substrate 210 may be ground using grinding equipment AP. Here, the upper end portion of the semiconductor substrate 210 with a thickness of approximately 700 μm may be removed using the grinding equipment AP. The integrated devices within the semiconductor substrate 210 may not be removed by grinding.

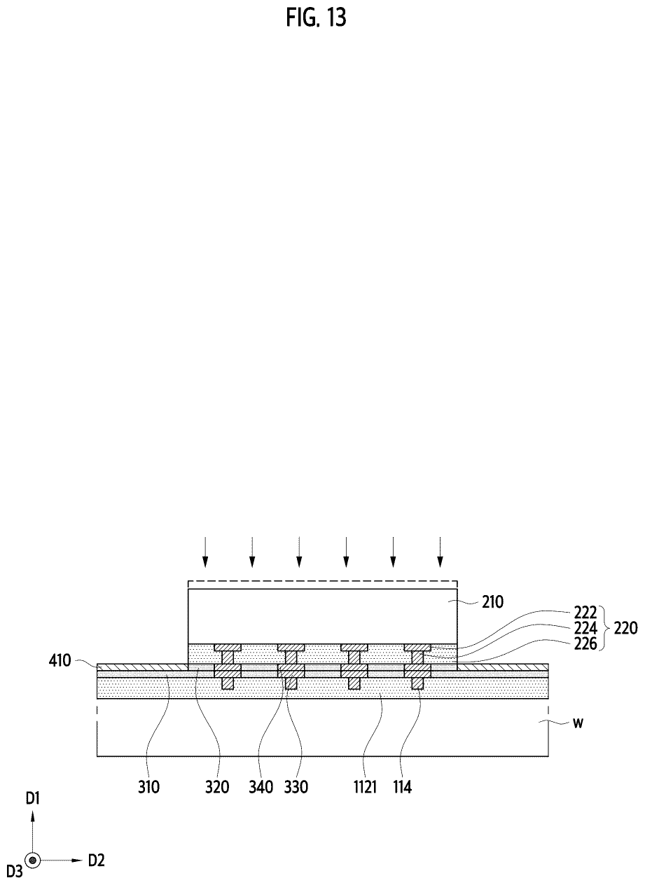

Referring to FIG. 13, the upper end portion of the ground semiconductor substrate 210 may be additionally removed through an etching process. In the etching process, the plasma generated from a gas containing fluorine may be utilized. In the etching process, the bias power of the required ion energy may be more than 100 W. In the etching process, the upper end portion of the ground semiconductor substrate 210 may be removed at a speed of about 1 μm/min or greater, or about 1.5 μm/min or greater, or about 3 μm/min or greater, or about 5 μm/min or greater, or about 10 μm/min or greater.

According to an example embodiment, the etching process may be a process for etching a material included in the semiconductor substrate 210. For example, when the semiconductor substrate 210 contains silicon, the etching process may be a process for etching silicon material. The etching stop layer 410 completely covers the side surface of the upper bonding layer 320 and a portion of the upper surface of the lower bonding layer 310, and thus the lower bonding layer 310 and the upper bonding layer 320 may not be exposed in the etching process. The etching stop layer 410 may include a material having etching selectivity with respect to the semiconductor substrate 210, the lower bonding layer 310, and the upper bonding layer 320. Therefore, the upper end portion of the semiconductor substrate 210 is etched by the etching process, but the etching stop layer 410 is hardly etched. Since the etching stop layer 410 is hardly etched, the lower bonding layer 310 and the upper bonding layer 320 covered by the etching stop layer 410 may also not be etched. In addition thereto, since the lower bonding layer 310 and the upper bonding layer 320 do not come into contact with the outside, the oxidation may be prevented in the etching process. The process for etching the upper end portion of the semiconductor substrate 210 may include dry etching process or wet etching process.

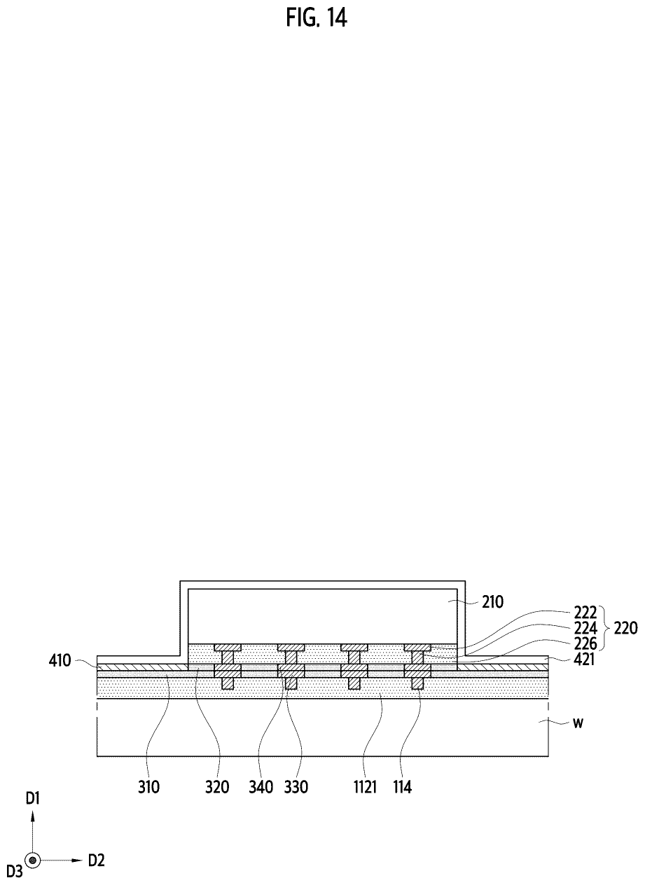

Referring to FIG. 14, a stopper material 421 may be formed that is configured to cover an upper surface of the etching stop layer 410, a side surface of the semiconductor chip 200, and the upper surface of the semiconductor chip 200. Specifically, the stopper material 421 may cover a portion of the side surface of the chip interconnection insulating layer 226 of the semiconductor chip 200. The stopper material 421 may be conformally extended along the upper surface of the etching stop layer 410, the side surface of the semiconductor chip 200, and upper surface of the semiconductor chip 200 with a uniform thickness. The atomic layer deposition ALD method may be used as a process for forming the stopper material 421, but the process for forming the stopper material 421 is not limited to the above.

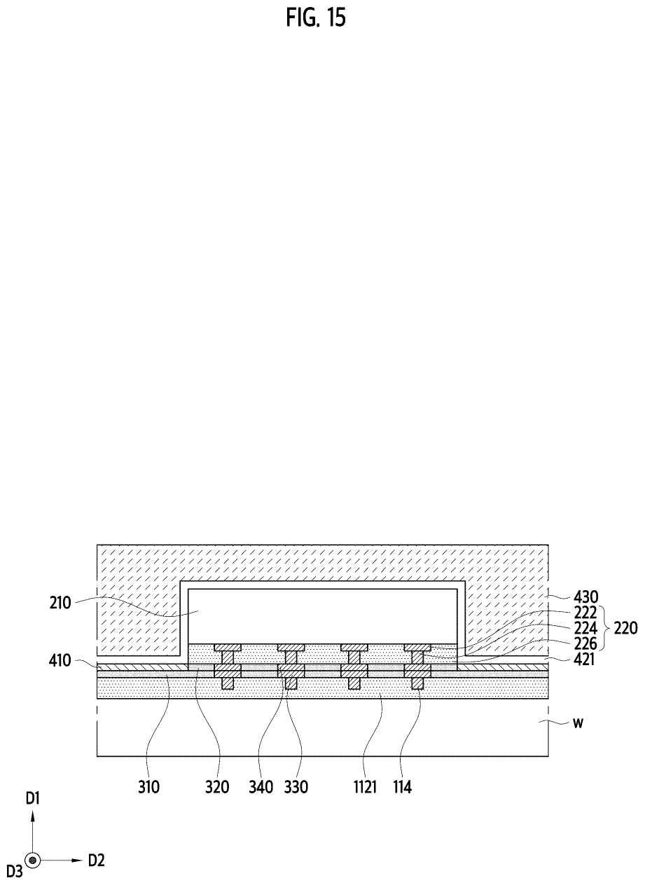

Referring to FIG. 15, the gap-fill layer 430 covering the stopper material 421 may be formed to seal the semiconductor chip 200. The gap-fill layer 430 may be formed thick enough to completely cover the semiconductor chip 200 and the stopper material 421. At this time, the vertical level of the upper surface of the gap-fill layer 430 may be formed higher than the vertical level of the top surface of the stopper material 421.

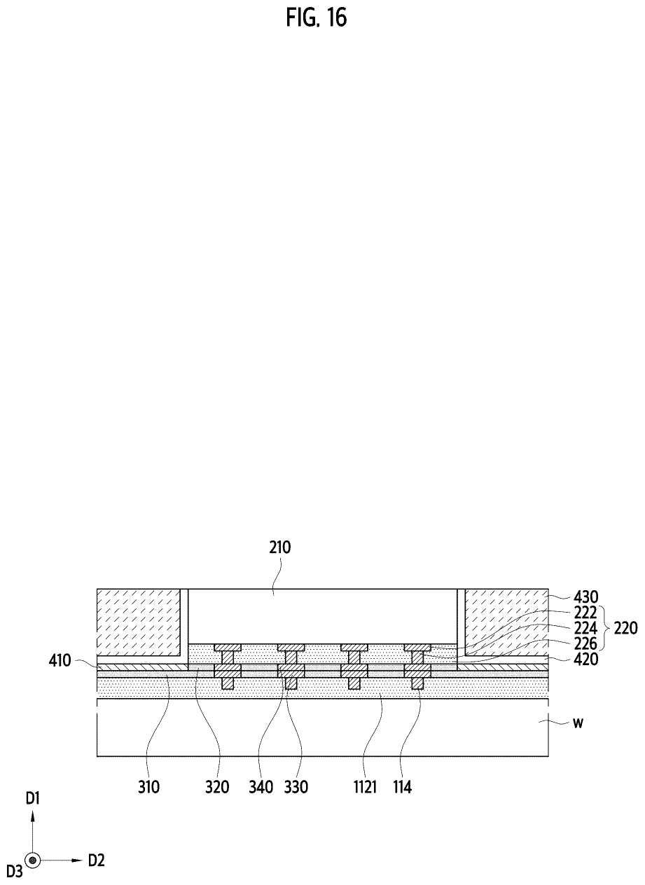

Referring to FIG. 16, in the CMP process, the upper end portion of the gap-fill layer 430 and the upper end portion of the stopper material 421 may be removed. The stopper 420 is completed by removing the upper end portion of the stopper material 421. In the process of polishing the gap-fill layer 430 using the CMP process, the stopper 420 provided on the upper surface of the semiconductor substrate 210 may prevent the semiconductor substrate 210 from being polished by utilizing the difference in polishing ratio, or may serve to indicate the position of the semiconductor substrate 210. Therefore, in the CMP process, only the stopper material 421 may be removed, and the semiconductor substrate 210 may not be removed. However, according to an example embodiment, together with the stopper material 421, a very small portion of the upper end portion of the semiconductor substrate 210 may be removed. The top surface of the completed stopper 420 that is formed by a portion of the stopper material being removed may be placed to be coplanar with the upper surface of the semiconductor chip 200 and the upper surface of the gap-fill layer 430.

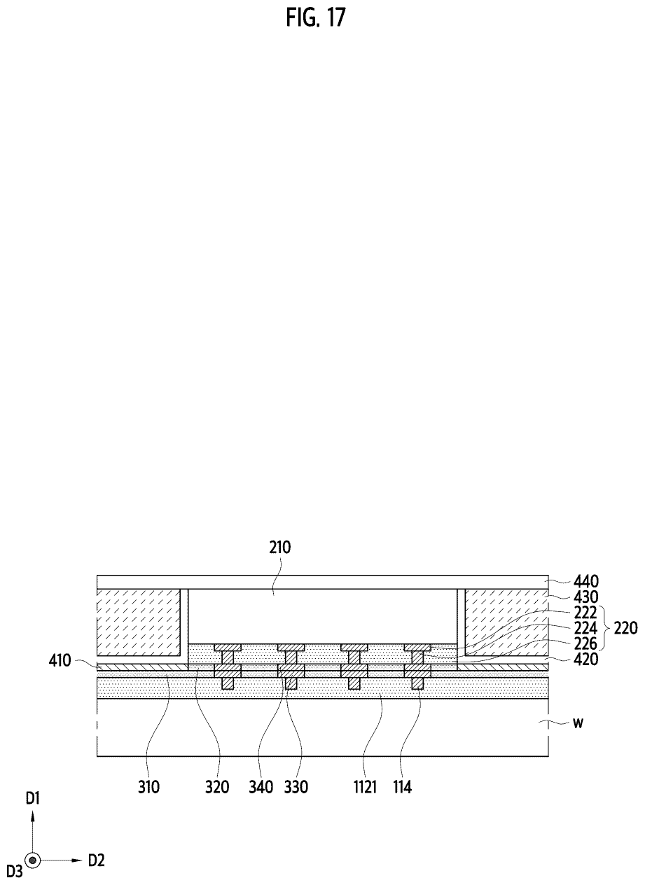

Referring to FIG. 17, after then, the heat dissipation member 440 may be formed on the gap-fill layer 430. The heat dissipation member 440 may extend along the upper surface of the gap-fill layer 430, the upper surface of the semiconductor substrate 210, and the top surface of the stopper 420. The heat dissipation member 440 may quickly dissipate heat received from the semiconductor chip 200 to the outside. The heat dissipation member 440 may include a thermal conductive material. The thermal conductive material may include a metal (for example, copper and/or aluminum) or a carbon-containing material (for example, graphene, graphite, and/or carbon nanotubes). The heat dissipation member 440 may have relatively high thermal conductivity. In an example embodiment, a single metal layer or multiple laminated metal layers may be used as the heat dissipation member 440. In an example embodiment, the heat dissipation member 440 may include a heat sink or a heatpite.

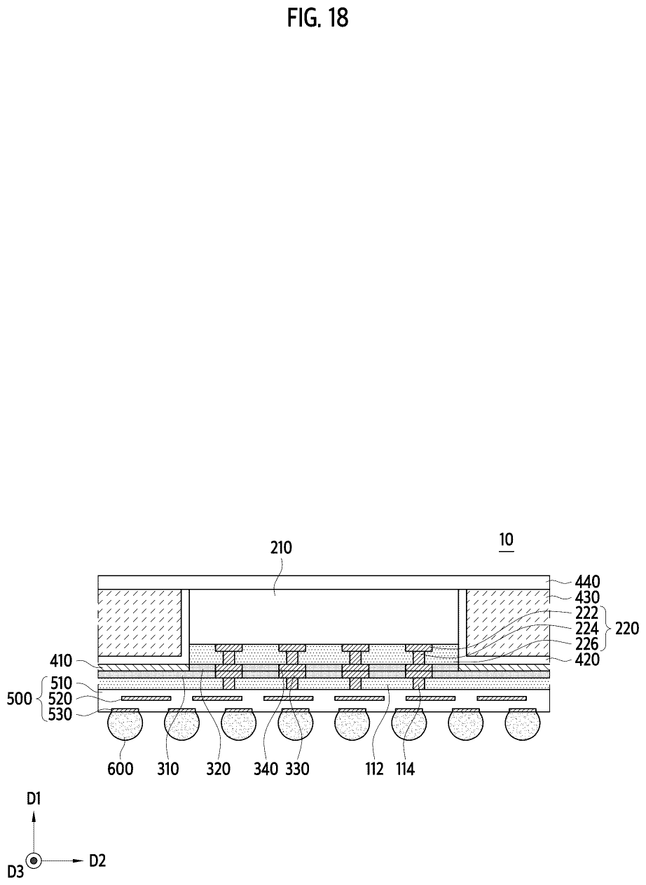

Referring to FIG. 18, after wafer W is detached from the insulating layer 112, a portion of the lower end portion of the insulating material 1121 may be removed. The process for removing a portion of the lower end portion of the insulating material 1121 may be used as a polishing process, but the process is not limited thereto. According to an example embodiment, the process of removing part of the lower end portion of the insulating material 1121 may be used as the etching process. The insulating layer 112 may be completed by removing a portion of the lower end portion of the insulating material 1121. Here, the lower surface of the via 114, which was embedded within the insulating layer 112, may be exposed.

According to an example embodiment, after removing a portion of the lower end portion of the insulating layer 112, the redistribution structure 500 may be formed on the lower surface of the insulating layer 112. In the present disclosure, the inactive surface of the semiconductor chip 200 is depicted facing upward along the first direction D1. However, in an actual process, after positioning the inactive surface of the semiconductor chip 200 to face downward along the first direction D1, the redistribution structure 500 may be formed on the insulating layer 112.

According to an example embodiment, the redistribution structure 500 may be formed to include the redistribution insulating layer 510, the plurality of redistribution patterns 520, and the plurality of redistribution pads 530. In the present disclosure, the plurality of redistribution patterns 520 are depicted as being laterally spaced (the second direction D2 and/or the third direction D3) on the same plane. However, according to an example embodiment, the plurality of redistribution patterns 520 may be provided in a multi-layer structure by varying the vertical level along the first direction D1. Even though not illustrated in detail, a redistribution via may be formed connecting the plurality of redistribution patterns 520 of a multilayer structure. In the present disclosure, the redistribution pattern 520 and the via 114 are depicted as being spaced apart in the first direction D1, but in reality, the via 114 and the redistribution pattern 520 may be physically connected. The plurality of redistribution pads 530 may be spaced apart along the lower surface of the redistribution insulating layer 510.

According to an example embodiment, after forming the redistribution structure 500, the external connection terminal 550 may be attached to each of the plurality of redistribution pads 530.

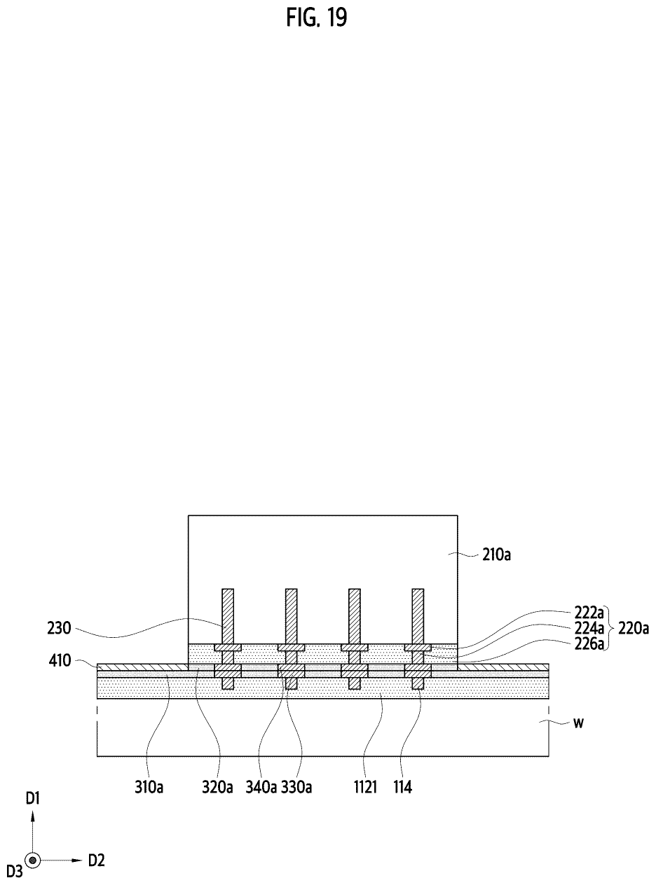

FIG. 19 to FIG. 23 are cross-sectional views sequentially illustrating an operation of a process for manufacturing a semiconductor package illustrated in FIG. 6.

The manufacturing process of the semiconductor package illustrated in FIG. 19 is a drawing illustrating a process corresponding to the manufacturing process of the semiconductor package illustrated in FIG. 10. Omitted is the description of the process that is repeating the description on the process for manufacturing a semiconductor package described with reference to FIG. 8 to FIG. 10.

Referring to FIG. 19, the first etching stop layer 410a may be formed on the upper surface of the first lower bonding layer 310a that does not overlap with the first upper bonding layer 320a. The first etching stop layer 410a may contact the upper surface of the lower bonding layer 310, and the same time, may be formed to completely cover the side surface of the upper bonding layer 320. The process for forming the etching stop layer 410 illustrated in FIG. 19 is substantially the same as the process for forming the etching stop layer 410 described with reference to FIG. 10, and thus any duplicate explanations below are omitted.

According to an example embodiment, in the first semiconductor substrate 210a, a plurality of first through electrodes 230 may be arranged to penetrate at least a portion of the first semiconductor substrate 210a. The lower surface of each of the plurality of first through electrodes 230 may be exposed to the lower surface of the first semiconductor substrate 210a. The lower end portion of each of the plurality of first through electrodes 230 may be connected to the first chip interconnection structure 220a. According to an example embodiment, the lower end portion of each of the plurality of first through electrodes 230 may be connected to the upper surface of the first chip interconnection pattern 222 of the first chip interconnection structure 220a.

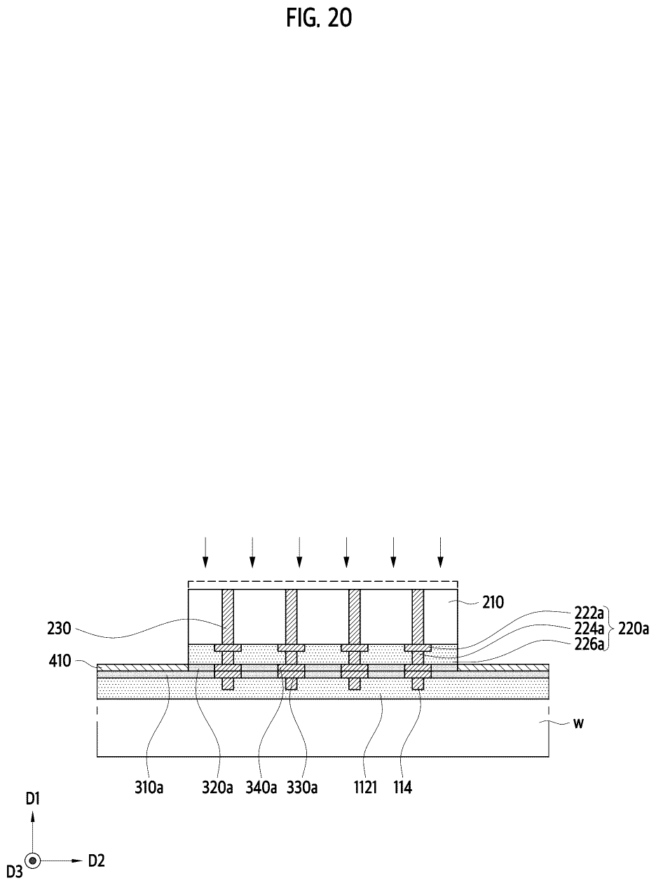

Referring to FIG. 20, after forming the first etching stop layer 410a on the first lower bonding layer 310a, the upper end portion of the first semiconductor substrate 210a may be ground through a grinding process. A specific description thereof is repeating the description of the grinding process for the upper end portion of the semiconductor substrate 210a with reference to FIG. 12, and thus the specific description is omitted.

After then, the upper end portion of the ground first semiconductor substrate 210a may be additionally removed through the etching process. A specific description of the etching process is repeating the description of the etching process for the upper end portion of the semiconductor substrate 210a with reference to FIG. 13, and thus the specific description is omitted.

According to an example embodiment, in the etching process for the upper end portion of the first semiconductor substrate 210a, a portion of the upper end portion of the first semiconductor substrate 210a may be removed. Here, until the upper surface of the first semiconductor substrate 210a is exposed to the upper surfaces of the plurality of first through electrodes 230, the etching process may be performed on the upper surface of the first semiconductor substrate 210a.

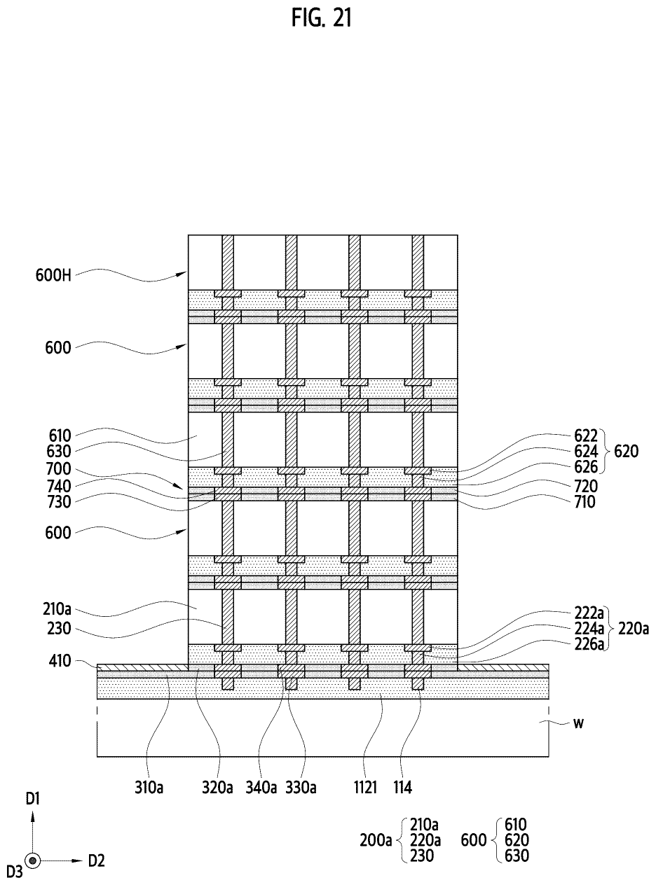

Referring to FIG. 21, the plurality of second semiconductor chips 600 are sequentially positioned on the first semiconductor substrate 210a. The second lower bonding layer 710 and the second lower bonding pad 730 are formed on the upper surface of the first semiconductor substrate 210a through which the plurality of first electrodes 230 are exposed. The second lower bonding pad 730 may be formed to contact the plurality of first through electrodes 230. The second lower bonding layer 710 may be formed to be in contact with the upper surface of the first semiconductor substrate 210a through which the first electrode 230 is not exposed.

According to an example embodiment, after forming the second lower bonding layer 710 and the second lower bonding pad 730, similar to what is described with reference to FIG. 8, the second semiconductor substrate 610 having the second upper bonding layer 720 and the second upper bonding pad 740 provided on the lower end portion may be attached to the second lower bonding layer 710. Here, in order for the second lower bonding pad 730 and the second upper bonding pad 740 to be aligned and in contact with each other, the second semiconductor substrate 610 may be aligned with the first semiconductor substrate 210a.

After then, after sequentially forming the second lower bonding layer 710 and the second lower bonding pad 730 on the second semiconductor substrate 610, another second semiconductor substrate 610 equipped with another second upper bonding layer 720 and another second upper bonding pad 740 may be positioned on the second lower bonding layer 710 and the second lower bonding pad 730. According to an example embodiment, sequentially stacked may be the second semiconductor substrates 610 on which the second lower bonding layer 710 and the second lower bonding pad 730 are already formed on the upper surface, and the second upper bonding layer 720 and the second upper bonding layer 720 are already formed on the lower surface.

According to an example embodiment, the plurality of second through electrodes 630 may be formed within the second semiconductor substrate 610 and spaced laterally (the first direction D1 and/or the second direction D2). The plurality of second through electrodes 630 may be formed to penetrate at least a portion of the second semiconductor substrate 610. The upper surfaces of the plurality of second through electrodes 630 may be exposed to the upper surface of the second semiconductor substrate 610, and the lower surfaces of the plurality of second through electrodes 630 may be exposed to the lower surface of the second semiconductor substrate 610.

According to an example embodiment, the second chip interconnection structure 620 may be provided on the lower surface of the second semiconductor substrate 610. The second chip interconnection structure 620 may be placed between the second semiconductor substrate 610 and the second upper bonding layer 720. The second chip interconnection pattern 622 of the second chip interconnection structure 620 may be connected to the second through electrode 630. The second chip interconnection via 624 may connect between the second chip interconnection pattern 622 and the second upper bonding pad 740. The second chip interconnection insulating layer 626 may embed the second chip interconnection pattern 622 and the second chip interconnection via 624.

As described with reference to FIG. 9, after attaching the second lower bonding layer 710 and the second upper bonding layer 720, and after attaching the second lower bonding pad 730 and the second upper bonding pad 740, the hybrid bonding may be achieved by applying heat and pressure. A detailed description thereof is repeating the description with reference to FIG. 9, and thus the detailed description is omitted.

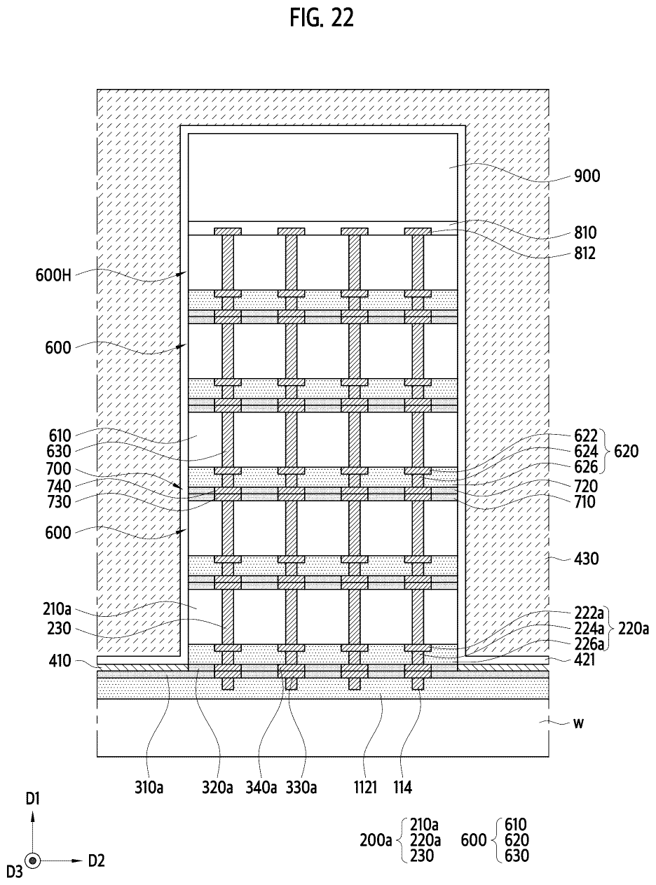

Referring to FIG. 22, the supporting dummy substrate 900 may be attached after the supportive binding insulation layer 810 and the upper surface chip connecting pad 812 are formed on the upper surface of the uppermost second semiconductor substrate 610. Here, each upper surface chip connecting pad 812 may be attached to the upper surface of the second through electrode 630 of the uppermost second semiconductor substrate 610. The supporting dummy substrate 900 may be positioned on the uppermost second semiconductor substrate 610, by using the edge of the uppermost second semiconductor substrate 610 as an align key.

After then, the stopper material 421 may be formed that is configured to cover the upper surface of the etching stop layer 410, the side surface of the first semiconductor chip 200a, the side surfaces of the plurality of second semiconductor chips 600, the side surface of the supportive binding insulation layer 810, and the side surfaces and the upper surface of the supporting dummy substrate 900. Specifically, with a uniform thickness, the stopper material 421 may be conformally extended along the upper surface of the etching stop layer 410, the side surface of the first semiconductor chip 200a, the side surfaces of the plurality of second semiconductor chips 600, the side surface of the supportive binding insulation layer 810, and the side surfaces and the upper surface of the supporting dummy substrate 900. The atomic layer deposition ALD method may be used in a process for forming the stopper material 421, but the process for forming the stopper material 421 is not limited thereto.

After then, by forming the gap-fill layer 430 that covers the stopper material 421, the first semiconductor chip 200a, the plurality of second semiconductor chips 600, and the supporting dummy substrate 900 may be sealed. The gap-fill layer 430 may be formed thick enough to completely cover the stopper material 421. Here, the vertical level of the upper surface of the gap-fill layer 430 may be formed higher than the vertical level of the top surface of the stopper material 421.

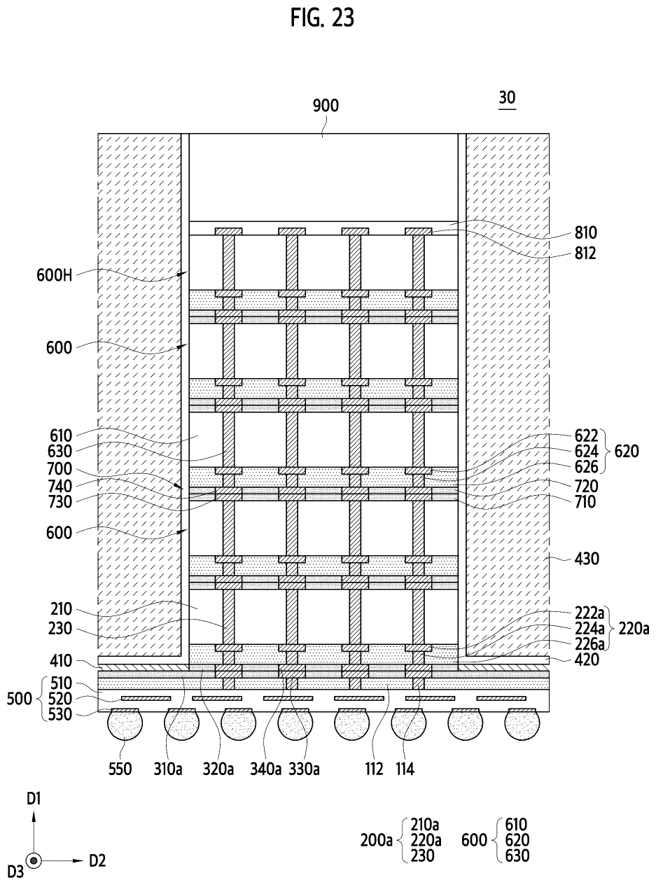

Referring to FIG. 23, in the CMP process, the upper end portion of the gap-fill layer 430 and the upper end portion of the stopper material 421 may be removed. The stopper 420 is completed by removing the upper end portion of the stopper material 421. Description on the process of removing the gap-fill layer 430 and the upper end portion of the stopper material 421 in the CMP process is repeating the description with reference to FIG. 16, and thus specific description is omitted.

After then, after a portion of the lower end portion of the insulating material 1121 is removed, the redistribution structure 500 may be formed on the lower surface of the insulating layer 112. The process of forming the redistribution structure 500 is identical to the description with reference to FIG. 18, and thus specific description is omitted.

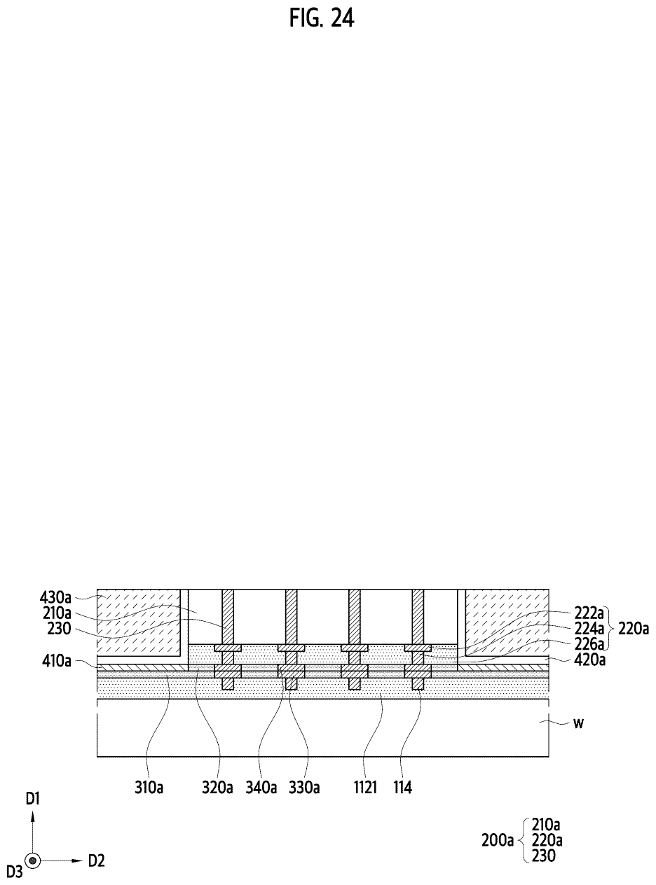

FIG. 24 to FIG. 28 are cross-sectional views sequentially illustrating an operation of a process for manufacturing the semiconductor package 40 illustrated in FIG. 7.

FIG. 24 is a drawing illustrating a process of manufacturing a semiconductor package and is corresponding to the manufacturing process of the semiconductor package shown in FIG. 16. Omitted is description of the process that repeats the operations of the process for manufacturing a semiconductor package described with reference to FIG. 8 to FIG. 16.

According to an example embodiment, the insulating material 1121 with the via 114 embedded in the wafer W may be formed. On the insulating material 1121, the first lower bonding layer 310a having a first width corresponding to the insulating material 1121 may be formed. On the first lower bonding layer 310a, the first upper bonding layer 320a having a second width smaller than the first width of the first lower bonding layer 310a may be formed.

According to an example embodiment, the first etching stop layer 410a may be formed on the upper surface of the first lower bonding layer 310a that does not overlap with the first upper bonding layer 320a. The first etching stop layer 410a may be in contact with the upper surface of the first lower bonding layer 310a, and at the same time, may be formed to completely cover the side surface of the first upper bonding layer 320a. After then, the first stopper 420a may be formed to cover the upper surface of the first etching stop layer 410a and the side surface of the first semiconductor chip 200a. After then, the first gap-fill layer 430a may be formed covering the first stopper 420a. The upper surface of the first gap-fill layer 430a may be placed to be coplanar with the top surface of the first stopper 420a and the upper surface of the first semiconductor chip 200a.

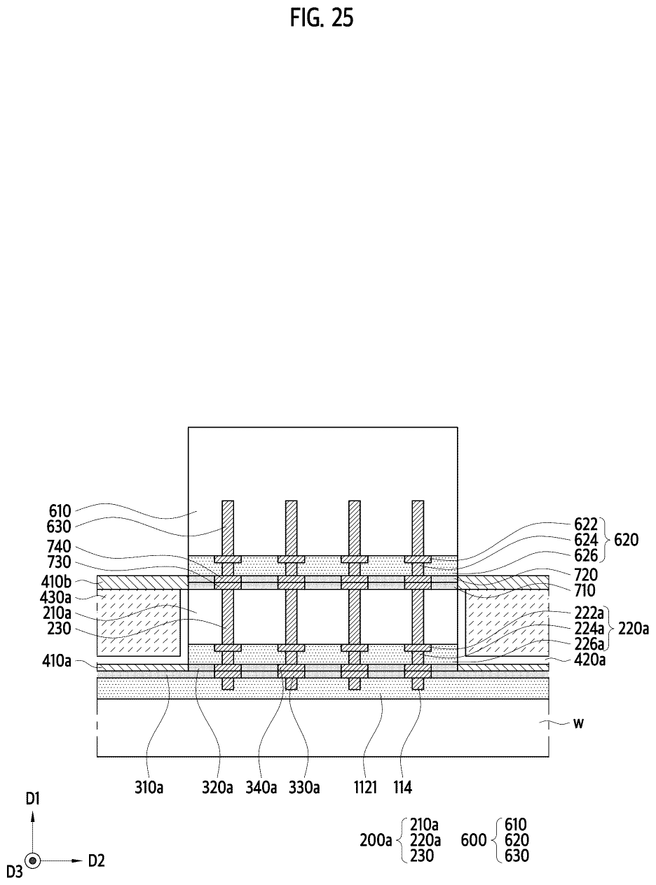

Referring to FIG. 25, the second lower bonding layer 710 and the second lower bonding pad 730 may be formed on the first semiconductor chip 200a. The second upper bonding layer 720 and the second upper bonding pad 740 may be formed on the second lower bonding layer 710 and the second lower bonding pad 730. The description on the process of forming the second lower bonding layer 710, the second lower bonding pad 730, the second upper bonding layer 720, and the second upper bonding pad 740 repeats the description with reference to FIG. 21, and thus, specific description is omitted.

After then, the second etching stop layer 410b may be formed on the first gap-fill layer 430a. The lower surface of the second etching stop layer 410b may contact the upper surface of the first gap-fill layer 430a and the top surface of the first stopper 420a. The second etching stop layer 410b may be positioned to contact the side surface of the second lower bonding layer 710 and the side surface of the second upper bonding layer 720. The thickness of the second etching stop layer 410b may be substantially equal to the sum of the thickness of the second lower bonding layer 710 and the thickness of the second upper bonding layer 720. The second etching stop layer 410b may cover the entire upper surface of the first gap-fill layer 430a, the entire side surface of the second lower bonding layer 710, and the entire side surface of the second upper bonding layer 720.

After then, the second semiconductor chip 600 may be attached on the second upper bonding layer 720. In order for the second chip interconnection via 624 of the second chip interconnection structure 620 to contact the second upper bonding pad 740, the second semiconductor chip 600 may be attached on the second upper bonding layer 720.

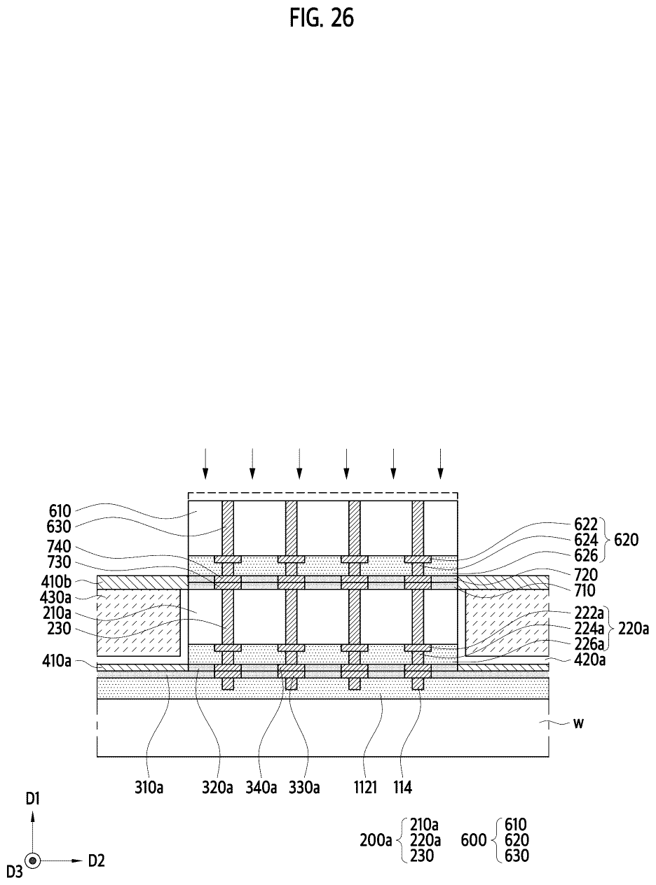

Referring to FIG. 26, the upper end portion of the second semiconductor substrate 610 may be ground and etched. The description of the process of grinding and etching the upper end portion of the second semiconductor substrate 610 repeats the description with reference to FIG. 20, and thus specific descriptions are omitted below. In the grinding and etching process, the plurality of second through electrodes 630 may be exposed to the upper surface of the second semiconductor substrate 610.

According to an example embodiment, the etching process may be a process for etching a material included in the second semiconductor substrate 610. The second etching stop layer 410b completely covers the side surface of the second upper bonding layer 720 and a portion of the upper surface of the second lower bonding layer 710, and thus the second lower bonding layer 710 and the second upper bonding layer 720 may not be exposed in the etching process. The upper end portion of the second semiconductor substrate 610 may be etched by an etching process, but the second etching stop layer 410b with etching selectivity may be hardly etched. Since the second etching stop layer 410b is hardly etched, the second lower bonding layer 710 and the second upper bonding layer 720 covered by the second etching stop layer 410b may also not be etched. In addition thereto, since the second lower bonding layer 710 and the second upper bonding layer 720 do not contact the outside, the oxidation may be prevented in the etching process.

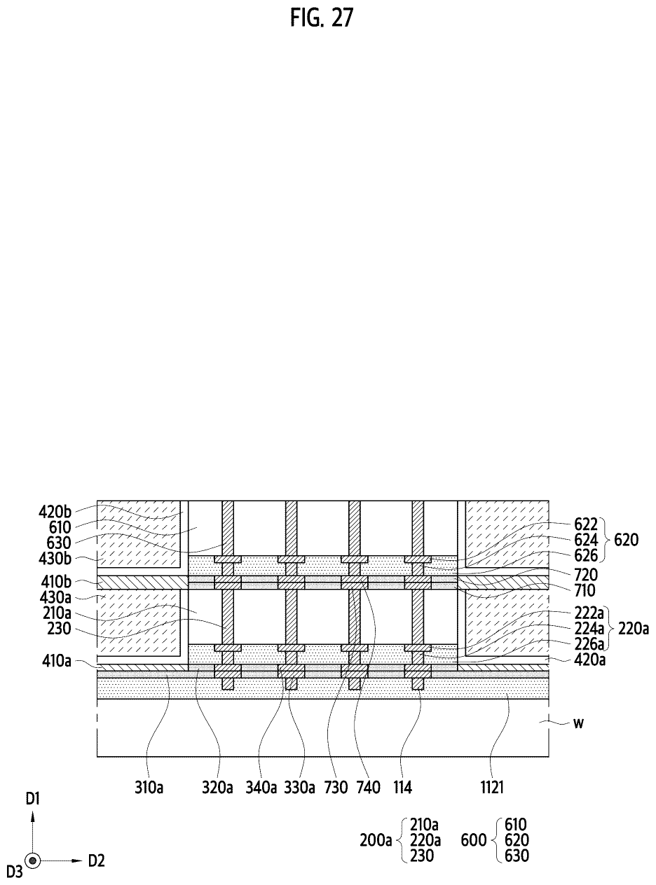

Referring to FIG. 27, after then, the second stopper 420b and the second gap-fill layer 430b may be formed. The second stopper 420b may cover the upper surface of the second etching stop layer 410b and the side surface of the second semiconductor chip 600. The second stopper 420b may cover the first gap-fill layer 430a. The upper surface of the second gap-fill layer 430b may be placed to be coplanar with the top surface of the second stopper 420b and the upper surface of the second semiconductor chip 600.

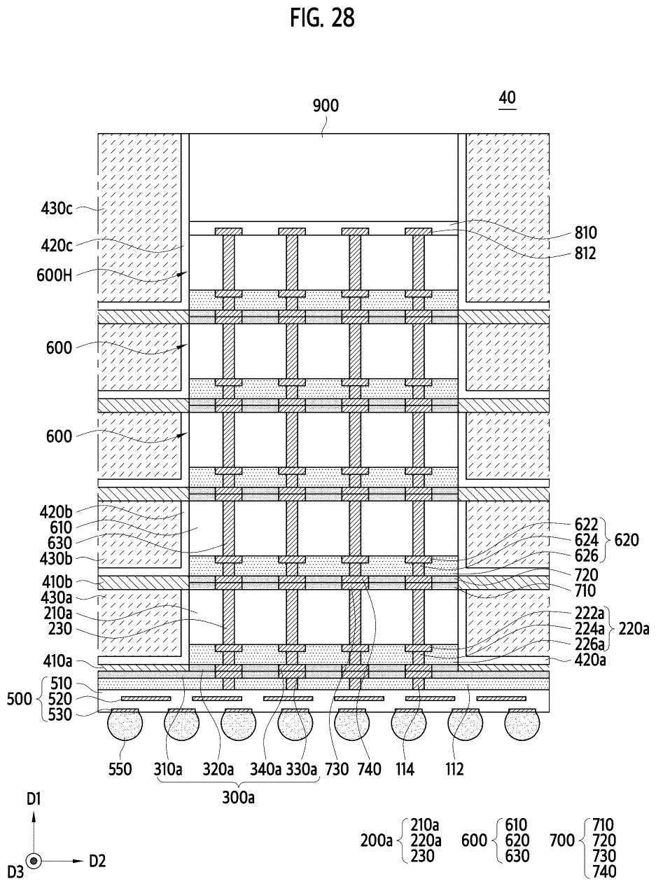

Referring to FIG. 27 and FIG. 28, the plurality of second semiconductor chips 600 are sequentially positioned on the wafer W. By repeating the processes described with reference to FIG. 25 to FIG. 27, the plurality of second etching stop layers 410b, the plurality of second stoppers 420b, and the plurality of second gap-fill layers 430b may be formed, and the plurality of second semiconductor chips 600 may be stacked using a hybrid bonding method.

After then, the supporting dummy substrate 900 may be attached after the supportive binding insulation layer 810 and the upper surface chip connecting pad 812 are formed on the upper surface of the uppermost second semiconductor substrate 610. Since the description thereof repeats the description with reference to FIG. 22, specific description is omitted.

After then, in the CMP process, the upper end portion of the third gap-fill layer 430c may be removed to form the third stopper 420c. The process of removing the upper end portion of the third gap-fill layer 430c and forming the third stopper 420c is identical to that described with reference to FIG. 16, and thus specific description is omitted.

After then, after a portion of the lower end portion of the insulating material 1121 is removed, the redistribution structure 500 may be formed on the lower surface of the insulating layer 112. Description on the process of forming the redistribution structure 500 repeats the description with reference to FIG. 18, and thus specific description is omitted.

As described above, example embodiments are disclosed with respect to the drawings in the present disclosure. In the present disclosure, the example embodiments are described using specific terms, but the terms are used solely for the purpose of explaining the technical ideas of the present disclosure and are not intended to limit the meaning or scope of the present disclosure as set forth in the claims. Therefore, those skilled in the art will understand that various modifications and equivalent example embodiments are possible from this.

What is claimed is:

1. A semiconductor package comprising:
a semiconductor chip comprising a semiconductor substrate and a chip interconnection structure;
an upper bonding layer in contact with the chip interconnection structure;
a lower bonding layer having a width greater than a width of the upper bonding layer, the lower bonding layer being dielectric-dielectric bonded with the upper bonding layer;
an upper bonding pad that is wrapped by the upper bonding layer;
a lower bonding pad that is wrapped by the lower bonding layer and is metal-metal bonded with the upper bonding pad; and
an etching stop layer covering a side surface of the upper bonding layer and an upper surface of the lower bonding layer.

2. The semiconductor package of claim 1, wherein the etching stop layer includes an upper surface that is coplanar with an upper surface of the upper bonding layer.

3. The semiconductor package of claim 1, wherein the etching stop layer extends along the upper surface of the lower bonding layer with a uniform thickness.

4. The semiconductor package of claim 1, wherein the etching stop layer includes a curved upper surface.

5. The semiconductor package of claim 1, wherein the etching stop layer has a thickness in a range from 200 nm to 400 nm.

6. The semiconductor package of claim 1, further comprising a stopper covering the upper surface of the etching stop layer and a side surface of the semiconductor chip.

7. The semiconductor package of claim 6, wherein the stopper has a thickness in a range from 300 nm to 600 nm.

8. The semiconductor package of claim 6, wherein the stopper includes an upper surface coplanar with an upper surface of the semiconductor chip.

9. The semiconductor package of claim 1, wherein the etching stop layer includes a material having an etching selectivity with respect to the semiconductor substrate, the upper bonding layer and the lower bonding layer.

10. The semiconductor package of claim 1, wherein the etching stop layer includes AlO.

11. The semiconductor package of claim 1, wherein the upper bonding layer and the lower bonding layer includes at least one of SiO, SiN, SiCN, or SiCO.

12. A semiconductor package comprising:
a first semiconductor chip comprising a first semiconductor substrate with an active surface and an inactive surface that are opposite to each other, a plurality of first through electrodes penetrating the first semiconductor substrate, and a first chip interconnection structure on the active surface of the first semiconductor substrate;
a plurality of second semiconductor chips each of which includes a second semiconductor substrate with an active surface and an inactive surface that are opposite to each other, a plurality of second through electrodes penetrating the second semiconductor substrate, and a second chip interconnection structure on the active surface of the second semiconductor substrate;
a first upper bonding layer in contact with the first chip interconnection structure;
a first lower bonding layer having a width greater than a width of the first upper bonding layer, the first lower bonding layer being dielectric-dielectric bonded with the first upper bonding layer;
a first upper bonding pad that is wrapped by the first upper bonding layer;
a first lower bonding pad that is wrapped by the first lower bonding layer, and is metal-metal bonded with the first upper bonding pad;
a second upper bonding layer on the inactive surface of the first semiconductor chip;
a second lower bonding layer being dielectric-dielectric bonded with the second upper bonding layer;
a second upper bonding pad that is wrapped by the second upper bonding layer;
a second lower bonding pad that is wrapped by the second lower bonding layer, and is metal-metal bonded with the second upper bonding pad; and
a first etching stop layer covering an upper surface of the first lower bonding layer that does not overlap the first upper bonding layer, and a side surface of the first upper bonding layer.

13. The semiconductor package of claim 12, a stopper covering an upper surface of the first etching stop layer, a side surface of the first semiconductor chip and side surfaces of the plurality of second semiconductor chips; and
a gap-fill layer wrapping the stopper.

14. The semiconductor package of claim 13, further comprising a supporting dummy substrate on a uppermost second semiconductor chip among the plurality of second semiconductor chips,
wherein the stopper includes an upper surface coplanar with an upper surface of the supporting dummy substrate.

15. The semiconductor package of claim 12, comprising:
a first stopper covering the upper surface of the first etching stop layer and the side surface of the first semiconductor chip;
a first gap-fill layer wrapping the first stopper;
a second etching stop layer covering a side surface of the second upper bonding layer and a side surface of the second lower bonding layer;
a second stopper covering an upper surface of the second etching stop layer and a side surface of one of the plurality of second semiconductor chips; and
a second gap-fill layer wrapping the second stopper.

16. The semiconductor package of claim 15, wherein the second etching stop layer has a thickness substantially equal to a sum of a thickness of the second upper bonding layer and a thickness of the second lower bonding layer.

17. The semiconductor package of claim 12, wherein the first chip interconnection structure comprises:
a chip interconnection insulating layer that extends along an upper surface of the first upper bonding layer;
a chip interconnection pattern in contact with the first through electrode; and
a chip interconnection via connecting the first upper bonding pad and the chip interconnection pattern.

18. The semiconductor package of claim 12, further comprising:
a redistribution structure under the first semiconductor chip; and
a connection structure that is between the redistribution structure and the first semiconductor chip, and includes a via connected with the redistribution structure.

19. A semiconductor package comprising:
a redistribution structure;
a semiconductor chip comprising a semiconductor substrate with an active surface and an inactive surface that are opposite to each other on the redistribution structure, and a chip interconnection structure on the active surface of the semiconductor substrate;
an upper bonding layer that is in contact with the chip interconnection structure and has a first width;
a lower bonding layer that is in contact with the upper bonding layer under the upper bonding layer and has a second width greater than the first width;
an upper bonding pad wrapped by the upper bonding layer;
a lower bonding pad that is wrapped by the lower bonding layer, and is in contact with the upper bonding pad;
an etching stop layer extending along an upper surface of the lower bonding layer that does not overlap the upper bonding layer and a side surface of the upper bonding layer, the etching stop layer including a material having an etching selectivity with respect to the upper bonding layer and the lower bonding layer;
a stopper that extends along an upper surface of the etching stop layer and a side surface of the semiconductor chip; and
a gap-fill layer wrapping the stopper,
wherein the upper surface of the etching stop layer is coplanar with an upper surface of the upper bonding layer.

20. The semiconductor package of claim 19, wherein the etching stop layer has a thickness in a range from 200 nm to 400 nm,
and the stopper has a thickness that is in a range from 300 nm to 600 nm.
